(19) United States
(12) Patent Application Publication
(10) Pub. No.: US 2009/0142715 A1
(43) Pub. Date: Jun. 4, 2009

(54) LAMINATED RESIST USED FOR IMMERSION LITHOGRAPHY

(75) Inventors: Takayuki ARAKI, Settsu-shi (JP); Tsuneo Yamashita, Settsu-shi (JP); Takuji Ishikawa, Settsu-shi (JP)

Correspondence Address: SUGHRUE MION, PLLC, 2100 PENNSYLVANIA AVENUE, N.W., SUITE 800, WASHINGTON, DC, 20037, US

(73) Assignee: DAIKIN INDUSTRIES LTD., Osaka-shi (JP)

(21) Appl. No.: 12/354,564

(22) Filed: Jan. 15, 2009

Related U.S. Application Data
(63) Continuation of application No. 10/589,504, filed on Aug. 15, 2006.

(30) Foreign Application Priority Data
Feb. 20, 2004 (JP) 2004-45010
Mar. 1, 2004 (JP) 2004-56678
Mar. 19, 2004 (JP) 2004-80378
Oct. 6, 2004 (JP) 2004-294082

(51) Int. Cl. G03F 7/20

(52) U.S. Cl. 430/326

(57) ABSTRACT

There is provided a laminated resist which is transparent in the case of exposure light of not less than 193 nm and can form a fine pattern having an intended form without defects with good reproducibility. The laminated resist has a photoresist layer (L1) and a transparent protective layer (L2) on a substrate and the protective layer (L2) is formed on an outermost surface of the laminated resist. The protective layer (L2) has an absorption coefficient of not more than 1.0 μm⁻¹ in the case of ultraviolet light of a wavelength of not less than 193 nm, a dissolution rate in a developing solution of not less than 50 nm/sec and a dissolution rate in pure water of not more than 10 nm/min.

### CROSS REFERENCE TO RELATED APPLICATION

This application is a continuation of U.S. application Ser. No. 10/589,504 filed Aug. 15, 2006, which is a National Stage Application filed under §371 of PCT Application No. PCT/JP2005/002133 filed Feb. 14, 2005, which claims benefit of JPA No. 2004-045010 filed Feb. 20, 2004, JPA No. 2004-056678 filed Mar. 1, 2004, JPA No. 2004-080378 filed Mar. 19, 2004 and JPA No. 2004-294082 filed Oct. 6, 2004. The above-noted applications are incorporated herein by reference in their entirety.

### TECHNICAL FIELD

The present invention relates to a laminated resist for forming a fine pattern in production of semiconductor devices, and relates to a laminated resist particularly useful in immersion lithography using water as a liquid medium.

### BACKGROUND ART

Ultra-micro fabrication is needed for various electronic parts including semiconductor integrated circuit, and a resist is widely used in a technique for such fabrication. Also for multifunction and high density of electronic parts, an ultrafine resist pattern is required to be formed.

At present, in a photolithography technology for forming a resist pattern, a ArF lithography process in which exposing is carried out using ultraviolet light of a wavelength of 193 nm emitted from a ArF excimer laser is on the way to practical use as a leading edge technology.

In order to meet the requirements for forming further fine pattern for the coming generation, a F2 lithography process is under development in which exposing is carried out with ultraviolet light of further shorter wavelength of 157 nm emitted from a F2 laser, and on the other hand, there are proposed lithography technologies being applicable to further microfabrication using a ArF exposure system used in ArF lithography under development for practical use.

One of those technologies under investigation is an immersion exposure technology in a ArF exposure system in which a clearance between the reduction projection glass and the wafer having a resist film thereon is filled with pure water (“Immersion Optical Lithography at 193 nm” (Jul. 11, 2003) Future Fab Intl. Volume 15 by Bruce W. Smith, Rochester Institute of Technology).

Though light is passed in the air having a refractive index of 1 in a conventional process (dry method), when passing light in pure water having a refractive index of 1.44, in the case of the same incident angle, theoretically it is possible to obtain minimum resolution (minimum pattern line width) of 1/1.44.

The ArF exposing using those immersion exposing technologies is expected since a further fine pattern can be formed without greatly modifying various processes and equipment which have already been developed.

For example, a conventional ArF resist which is transparent at 193 nm, namely a resist material containing, as main component, a hydrocarbon resin having an aliphatic ring structure is under investigation.

However since a clearance between the reduction projection glass and the resist film is filled with pure water at immersion exposing and the resist film comes into contact with pure water, the above-mentioned conventional ArF resist easily absorbs water. As a result, there arises a problem that diffusion and elution in pure water of a photoacid generator contained in the resist film and amine to be used as a quencher occur and good reproducibility of an intended pattern form is difficult to obtain.

Further a strength of the resist film is decreased remarkably and adhesion of the film to a substrate is lowered due to water absorption and swelling of the resist film. Therefore a strength of the formed resist pattern is low, and pattern defects such as falling and lacking of the pattern easily arise.

### DISCLOSURE OF INVENTION

The present invention was completed based on new findings obtained in intensive studies made to solve the mentioned problems. An object of the present invention is to provide a laminated resist in which the resist film has a specific layer construction, thereby being transparent to exposure light of a short wavelength such as ArF excimer laser and further making it possible to form a fine pattern of an intended form at immersion exposing with good reproducibility without causing pattern defects.

The present inventors have made intensive studies with respect to a resist film to be used for immersion exposing method using pure water as a medium, namely, a layer construction and kind of materials used therefor, and as a result, have found that when a laminated resist has a specific layer construction and is made of specific materials, an improvement can be made in solving the mentioned problems which have been difficult to solve only by a conventional resist material layer for ArF.

Namely, the first of the present invention relates to a laminated resist for immersion lithography using ultraviolet light of a wavelength of not less than 193 nm for exposing, in which a photoresist layer (L1) and a protective layer (L2) are formed on a substrate and the protective layer (L2) forms the outermost surface of the laminated resist and is characterized in that:

(1) an absorption coefficient in ultraviolet light of a wavelength of not less than 193 nm is not more than 1.0 μm⁻¹,
(2) a dissolution rate in a developing solution is not less than 50 nm/sec, and
(3) a dissolution rate in pure water is not more than 10 nm/min.

Also the second of the present invention relates to a laminated resist for immersion lithography using ultraviolet light of a wavelength of not less than 193 nm for exposing, in which a photoresist layer (L3) is formed on a substrate as an outermost surface of the laminated resist and is characterized by containing (A2) a fluorine-containing polymer having protective group Y² which can be converted to an alkali soluble group by dissociation with an acid and (B2) a photoacid generator.

### BRIEF DESCRIPTION OF DRAWING

FIG. 1 is a diagrammatic view for explaining each step (a) to (e) of the method of forming the first laminated resist of the present invention and the method of forming a fine pattern by immersion exposing.

### BEST MODE FOR CARRYING OUT THE INVENTION

As mentioned above, in the first of the present invention, the laminated resist has the photoresist layer (L1) and the protective layer (L2) on a substrate and the protective layer (L2) forms the outermost surface of the laminated resist and is characterized in that:

(1) an absorption coefficient in ultraviolet light of a wavelength of not less than 193 nm is not more than 1.0 μm⁻¹,
(2) a dissolution rate in a developing solution is not less than 50 nm/sec, and
(3) a dissolution rate in pure water is not more than 10 nm/min.

This laminated resist can be effectively applied to an exposing step of immersion lithography in which exposing is carried out using ultraviolet light of a wavelength of not less than 193 nm and pure water is used as a liquid medium.

Namely, in the first laminated resist of the present invention, the protective layer (L2) is further formed on the outermost surface of the resist film having the photoresist layer (L1) containing a conventional resist material such as ArF or KrF resist, and by using the protective layer (L2) having specific properties, an improvement can be made in solving problems arising due to contact with pure water.

In the first laminated resist of the present invention, the protective layer forming the outermost layer need be transparent to light having a wavelength of not less than 193 nm.

By using such a protective layer, an immersion exposing process using pure water can be utilized, for example, for ArF lithography using light having a wavelength of 193 nm and also KrF lithography using light having a wavelength of 248 nm.

Concretely in the case of a wavelength of not less than 193 nm, an absorption coefficient is not more than 1.0 μm⁻¹, preferably not more than 0.8 μm⁻¹, more preferably not more than 0.5 μm⁻¹, most preferably not more than 0.3 μm⁻¹.

A too large absorption coefficient of the protective layer (L2) is not preferred since transparency of the whole laminated resist is lowered, thereby lowering resolution at forming a fine pattern and resulting in deterioration of a pattern form.

Also it is preferable that the protective layer (L2) is difficult to dissolve in pure water or is low in a dissolution rate in pure water while having good solubility in a developing solution, for example, a 2.38% aqueous solution of tetramethylammonium hydroxide (2.38% aqueous solution of TMAH).

Concretely with respect to the dissolution rate in a developing solution, the dissolution rate of the layer in a 2.38% aqueous solution of TMAH which is measured by QCM method explained infra is not less than 50 nm/sec, preferably not less than 100 nm/sec, more preferably not less than 200 nm/sec, particularly preferably not less than 300 nm/sec.

A too low dissolution rate in a developing solution is not preferred since resolution is lowered at forming a fine pattern and the pattern easily becomes in the form of T-top, thereby making it difficult to obtain an intended pattern form.

On the other hand, it is preferable that the protective layer (L2) is difficult to dissolve in pure water. According to the measurement by the QCM method, the dissolution rate of the layer in pure water is not more than 10 nm/min, preferably not more than 8 nm/min, more preferably not more than 5 nm/min, particularly preferably not more than 2 nm/min.

A too high dissolution rate in pure water is not preferred since the protecting effect by the protective layer (L2) becomes insufficient and the effect of improvement in solving the above-mentioned problems becomes insufficient.

In the present invention, for the measurement of the dissolution rate in pure water, ion-exchanged water obtained by using a usual ion exchange membrane is used as pure water.

Also it is preferable that the protective layer (L2) has high water repellency to such an extent not to lower the dissolution rate in a developing solution remarkably.

For example, a water contact angle of the protective layer (L2) is preferably not less than 70°, more preferably not less than 75°, particularly preferably not less than 80°. An upper limit thereof is preferably not more than 100°, more preferably not more than 95°, particularly preferably not more than 90°.

If the water contact angle on the surface of the protective layer (L2) is too small, after coming into contact with pure water, water permeation becomes fast and water easily reaches the photoresist layer (L1), resulting in insufficient protecting effect by the protective layer (L2). Therefore a too small water contact angle is not preferred.

On the contrary, a too large water contact angle on the surface of the protective layer (L2) is not preferred because the dissolution rate in a developing solution is remarkably decreased.

Further the protective layer (L2) having a low water absorbing property (water absorbing rate) is preferred.

If the water absorbing property (water absorbing rate) is too high, after coming into contact with pure water, water permeation becomes fast and water easily reaches the photoresist layer (L1), resulting in insufficient protecting effect by the protective layer (L2). Therefore a too high water absorbing property is not preferred.

For example, the water absorbing property (water absorbing rate) can be measured by the QCM method, and calculated as a weight increasing rate (water absorbing rate) by water absorption.

It is preferable that the protective layer (L2) having such properties as mentioned above is prepared from a polymer material having a water-repellent or hydrophobic moiety and a hydrophilic moiety, for example, a polymer material having hydrophilic functional group Y.

It is particularly preferable that the protective layer (L2) is prepared from the fluorine-containing polymer (A1) having hydrophilic functional group Y since the polymer has high transparency even at a wavelength of not less than 193 nm and has a water-repellent or hydrophobic moiety.

Namely, it is preferable that the protective layer (L2) is a layer which is prepared from the fluorine-containing polymer (A1) having hydrophilic functional group Y and has the mentioned properties.

The hydrophilic functional group may be one being capable of imparting solubility in a developing solution, for example, a functional group containing acidic OH group having a pKa value of not more than 11, more preferably not more than 10, particularly preferably not more than 9.5.

Examples of the hydrophilic functional group Y are:

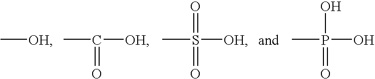

and among them, —OH group and —COOH group are preferred from the viewpoint of high transparency, and further —OH group is preferred from the point that water absorption can be decreased.

In order to obtain acidity in the pKa value of not more than 11, it is preferable that a fluorine-containing alkyl group or a fluorine-containing alkylene group is bonded to the carbon atom directly bonded to the OH group. Concretely preferred is a moiety represented by the following formula:

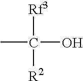

wherein Rf³ is a fluorine-containing alkyl group which has 1 to 10 carbon atoms and may have ether bond; R² is selected from hydrogen atom, hydrocarbon groups having 1 to 10 carbon atoms and fluorine-containing alkyl groups which have 1 to 10 carbon atoms and may have ether bond.

It is particularly preferable that R² is a fluorine-containing alkyl group which has 1 to 10 carbon atoms and may have ether bond.

Further it is preferable that both of Rf³ and R² are perfluoroalkyl groups, and concretely moieties represented by:

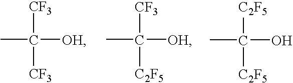

and the like are preferred.

Further from the viewpoint of decreasing water absorption and enhancing solubility in a developing solution, more preferred is a moiety represented by the following formula:

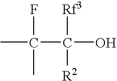

wherein Rf³ is a fluorine-containing alkyl group which has 1 to 10 carbon atoms and may have ether bond; R² is selected from hydrogen atom, hydrocarbon groups having 1 to 10 carbon atoms and fluorine-containing alkyl groups which have 1 to 10 carbon atoms and may have ether bond. Concretely preferred are moieties of:

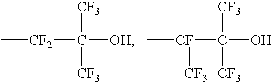

and the like.

It is preferable that the fluorine-containing polymer (A1) having hydrophilic functional group Y has a fluorine content of not less than 30% by mass, more preferably not less than 40% by mass, particularly preferably not less than 50% by mass.

A too low fluorine content is not preferred because water repellency is lowered and water absorption is increased.

An upper limit of the fluorine content is 75% by mass, preferably 70% by mass, more preferably 65% by mass.

A too high fluorine content is not preferred because water repellency becomes too high, thereby decreasing the dissolution rate in a developing solution and lowering reproducibility of the dissolution rate in a developing solution.

The first example of the preferred fluorine-containing polymer (A1) having hydrophilic functional group Y which is used for the protective layer (L2) of the first laminated resist of the present invention is one having a structural unit (M2) of an aliphatic ring structure in the polymer trunk chain.

The structural unit (M2) of an aliphatic ring structure in the trunk chain of the polymer can be usually obtained by polymerizing a monomer (m2) which can give the structural unit (M2) of an aliphatic ring structure to the trunk chain of the polymer. In the case that the monomer (m2) does not contain fluorine atom, fluorine atom is introduced to the polymer by copolymerizing other fluorine-containing monomer, concretely a fluorine-containing ethylenic monomer (m1).

The hydrophilic functional group Y may be contained in the structural unit M2 or may be contained in other structural unit.

The preferred fluorine-containing polymer (A1) having a structural unit of an aliphatic ring structure in its trunk chain is represented by the formula (M-1):

-(M1)-(M2)-(N1)-(N)- (M-1)

wherein the structural unit M1 is a structural unit derived from the fluorine-containing ethylenic monomer (m1) having 2 or 3 carbon atoms and at least one fluorine atom; the structural unit M2 is a structural unit derived from the monomer (m2) being capable of giving an aliphatic ring structure to the trunk chain of the polymer; the structural unit N1 is a structural unit derived from a monomer (n1) being copolymerizable with the monomer (m1) and monomer (m2); the structural unit N is a structural unit derived from a monomer (n) being copolymerizable with the monomer (m1), monomer (m2) and monomer (n1); at least either of the structural unit M2 or N1 has the hydrophilic functional group Y and when the structural unit M2 has Y, the structural unit N1 may be the same as the structural unit N, and

the structural units M1, M2, N1 and N are contained in amounts of from 1 to 99% by mole, from 1 to 99% by mole, from 0 to 98% by mole and from 0 to 98% by mole, respectively (when the structural unit M2 does not have the hydrophilic functional group Y, the structural unit N1 is essential).

In the fluorine-containing polymer of the formula (M-1), the fluorine-containing ethylenic monomer (m1) being capable of introducing fluorine atom to the trunk chain of the polymer is a fluorine-containing ethylenic monomer having one polymerizable, particularly radically polymerizable carbon-carbon double bond, 2 or 3 carbon atoms and at least one fluorine atom.

Such a fluorine-containing ethylenic monomer (m1) is a mono-ene compound having one polymerizable carbon-carbon double bond and does not form a structural unit having a ring structure in the trunk chain even by polymerization.

Since fluorine atom can be effectively introduced by the structural unit derived from the fluorine-containing ethylenic monomer (m1), in the case of use for the protective layer (L2), good water repellency, water resistance and water-proof property can be imparted to the polymer. Therefore the monomer (m1) is preferred and also is effective particularly from the viewpoint of transparency.

Preferred examples of the fluorine-containing ethylenic monomer (m1) are monomers in which at least one of hydrogen atoms of ethylene and propylene is replaced by fluorine atom. Other hydrogen atoms may be replaced by halogen atoms other than fluorine atom.

Particularly preferred are monomers in which at least one fluorine atom is bonded to the carbon atom constituting the carbon-carbon double bond, thereby making it possible to introduce fluorine atom to the structural unit (M1), namely to the polymer trunk chain and effectively obtain the fluorine-containing polymer giving especially excellent transparency in a vacuum ultraviolet region.

Concretely preferred example thereof is at least one monomer selected from tetrafluoroethylene, chlorotrifluoroethylene, vinylidene fluoride, vinyl fluoride, trifluoroethylene, hexafluoropropylene and CH₂═CFCF₃.

Particularly one or a mixture of two or more of tetrafluoroethylene, chlorotrifluoroethylene, vinylidene fluoride and hexafluoropropylene is preferred from the viewpoint of transparency. Especially preferred are tetrafluoroethylene and/or chlorotrifluoroethylene.

Then explained below is the monomer (m2) being capable of giving the structural unit (M2) of aliphatic ring structure to the trunk chain of the fluorine-containing polymer of the formula (M-1).

The monomer (m2) can introduce, to the polymer trunk chain, the structural unit (M2) of aliphatic ring structure which enhances dry etch resistance when used for the photoresist layer (L3) of the second of the present invention explained infra.

The monomer (m2) may be selected from unsaturated cyclic compounds having a radically polymerizable carbon-carbon unsaturated bond in its ring structure or may be selected from non-conjugated diene compounds which can form a ring structure in the polymer trunk chain by ring-forming polymerization.

Also the monomer (m2) may have or may not have the hydrophilic functional group Y therein.

By (co)polymerizing the monomer (m2), a polymer having an aliphatic ring structural unit of monocyclic structure or polycyclic structure in its trunk chain can be obtained.

In the present invention, “polycyclic structure” encompasses “bridged rings” such as bicyclo ring and tricycle ring among structures having plural rings, but does not encompass “fused ring”, “spiro ring” and “ring assemblies” such as monocondensation or polycondensation product and polycyclohexane having plural rings bonded with a spacer.

The first of the preferred monomer (m2) is the monomer (m2-1) which has a radically polymerizable carbon-carbon unsaturated bond, can form a monocyclic or polycyclic structure in the polymer trunk chain and does not have the hydrophilic functional group Y.

This monomer is concretely selected from a monomer (m2-1a) of a monocyclic aliphatic unsaturated hydrocarbon compound having no hydrophilic functional group Y, a monomer (m2-1b) of a polycyclic aliphatic unsaturated hydrocarbon compound having no hydrophilic functional group Y and a non-conjugated diene compound (m2-1c) explained infra which can be subjected to ring-forming polymerization and has no hydrophilic functional group Y.

It is preferable that the monocyclic monomer (m2-1a) having no hydrophilic functional group Y is an aliphatic unsaturated hydrocarbon compound of three- to eight-membered ring structure which may have ether bond in its ring structure.

Preferred examples of the monomer (m2-1a) are concretely:

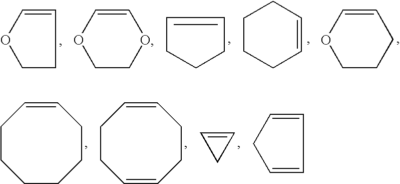

and the like.

Further in those monomers (m2-1a), a part or the whole of hydrogen atoms thereof may be substituted by fluorine atoms, and preferred examples are, for instance:

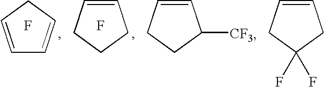

and the like.

Another monomer (m2-1) is the monomer (m2-1b) which introduces, to the polymer trunk chain, a structural unit having an aliphatic polycyclic structure and has an aliphatic polycyclic structure without the hydrophilic functional group Y. The preferred monomer (m2-1b) is a norbornene derivative.

Examples of the monomer (m2-1b) having an aliphatic polycyclic structure without the hydrophilic functional group Y are concretely:

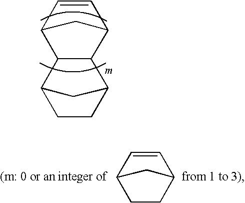

and the like.

The above-exemplified norbornenes may have fluorine atom introduced to the ring structure thereof. By introducing fluorine atom, water repellency, water resistance and water-proof property can be imparted and transparency can be enhanced without lowering dry etch resistance.

Concretely there are fluorine-containing norbornenes represented by the formula:

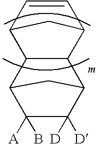

wherein A, B, D and D′ are the same or different and each is H, F, an alkyl group having 1 to 10 carbon atoms or a fluorine-containing alkyl group having 1 to 10 carbon atoms; m is 0 or an integer of from 1 to 3; any one of A, B, D and D′ contains fluorine atom. Examples thereof are fluorine-containing norbornenes represented by:

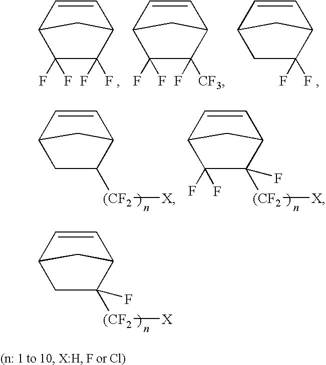

and the like.

Other examples thereof are norbornene derivatives represented by:

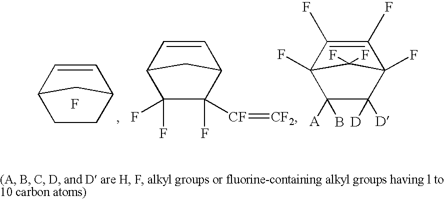

and the like.

The second of the preferred monomer (m2) is the monomer (m2-2) which has a radically polymerizable carbon-carbon unsaturated bond, can form a monocyclic or polycyclic structure in the polymer trunk chain and has the hydrophilic functional group Y.

This monomer is concretely selected from a monomer (m2-2a) of a monocyclic aliphatic unsaturated hydrocarbon compound having the hydrophilic functional group Y, a monomer (m2-2b) of a polycyclic aliphatic unsaturated hydrocarbon compound having the hydrophilic functional group Y and a monomer (m2-2c) of a non-conjugated diene compound explained infra which can be subjected to ring-forming polymerization and has the hydrophilic functional group Y.

It is preferable that the monocyclic monomer (m2-2a) having the hydrophilic functional group Y is an unsaturated hydrocarbon compound of three- to eight-membered ring structure which may have ether bond in its ring structure. A part or the whole of hydrogen atoms of the monomer (m2-2a) may be substituted by fluorine atoms like the monomer mentioned supra.

Examples of the monocyclic monomer (m2-2a) having the hydrophilic functional group Y are concretely:

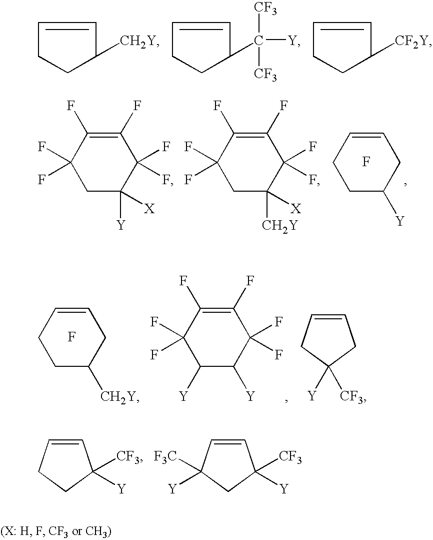

and the like.

Another monomer (m2-2) having the hydrophilic functional group Y is the monomer (m2-2b) having an aliphatic polycyclic structure which introduces, to the polymer trunk chain, a structural unit having an aliphatic polycyclic structure and has the hydrophilic functional group Y. The preferred monomer (m2-2b) is a norbornene derivative having the hydrophilic functional group Y.

Examples of the monomer (m2-2b) which has an aliphatic polycyclic structure and the hydrophilic functional group Y are concretely:

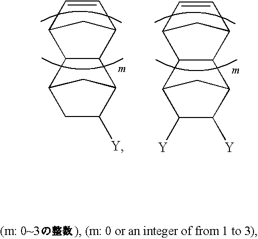

and the like.

Further the monomer (m2-2b) which has an aliphatic polycyclic structure and the hydrophilic functional group Y may be a monomer, in which a part or the whole of hydrogen atoms bonded to the ring structure are substituted by fluorine atoms. This monomer is preferred since water repellency, water resistance, water-proof property and transparency can be imparted more to the polymer.

Examples thereof are fluorine-containing norbornene derivatives represented by:

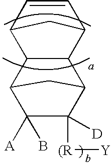

wherein A, B and D are the same or different and each is H, F, an alkyl group having 1 to 10 carbon atoms or a fluorine-containing alkyl group which has 1 to 10 carbon atoms and may have ether bond; R is a divalent hydrocarbon group having 1 to 20 carbon atoms, a fluorine-containing alkylene group having 1 to 20 carbon atoms or a fluorine-containing alkylene group having 2 to 100 carbon atoms and ether bond; a is 0 or an integer of from 1 to 5; b is 0 or 1; when b is 0 or R does not have fluorine atom, any one of A, B and D is a fluorine atom or a fluorine-containing alkyl group which has 1 to 10 carbon atoms and may have ether bond.

It is preferable that any of A, B or D is a fluorine atom or contains fluorine atom, and when fluorine atom is not contained in A, B and D, a fluorine content of R is not less than 50% by weight, more preferably not less than 60% by weight, particularly preferably not less than 70% by weight, and it is further preferable that R is a perfluoroalkylene group since transparency can be imparted to the polymer.

Examples thereof are the norbornene derivatives represented by:

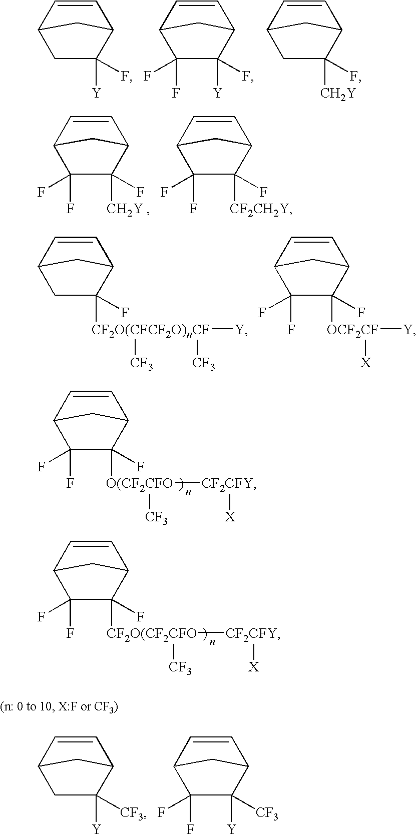

and the like.

Further there are fluorine-containing norbornene derivatives represented by:

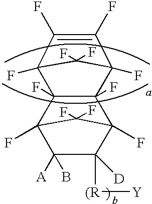

wherein A, B and D are the same or different and each is H, F, an alkyl group having 1 to 10 carbon atoms or a fluorine-containing alkyl group which has 1 to 10 carbon atoms and may have ether bond; R is a divalent hydrocarbon group having 1 to 20 carbon atoms, a fluorine-containing alkylene group having 1 to 20 carbon atoms or a fluorine-containing alkylene group having 2 to 100 carbon atoms and ether bond; a is 0 or an integer of from 1 to 5; b is 0 or 1.

Further preferred examples of the monomer (m2-2b) which has an aliphatic polycyclic structure and the hydrophilic functional group Y are fluorine-containing norbornene derivatives represented by:

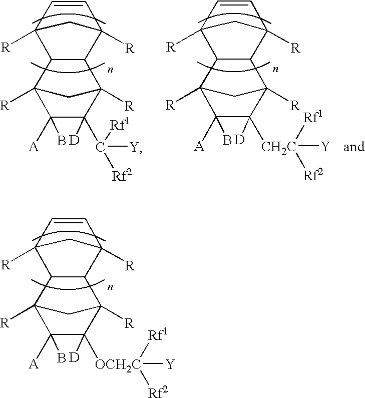

wherein Rf¹ and Rf² are the same or different and each is a fluorine-containing alkyl group having 1 to 10 carbon atoms or a fluorine-containing alkyl group which has 1 to 10 carbon atoms and ether bond; A, B and D are the same or different and each is H, F, Cl, an alkyl group having 1 to 10 carbon atoms or a fluorine-containing alkyl group which has 1 to 10 carbon atoms and may have ether bond; R is H or an alkyl group having 1 to 10 carbon atoms; n is 0 or an integer of from 1 to 5.

Examples thereof are, for instance:

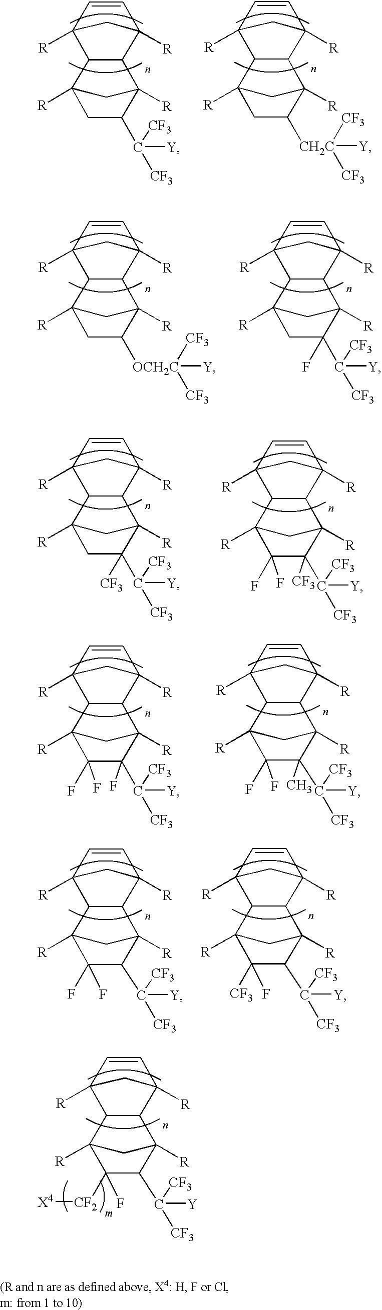

and the like.

Particularly there are preferably:

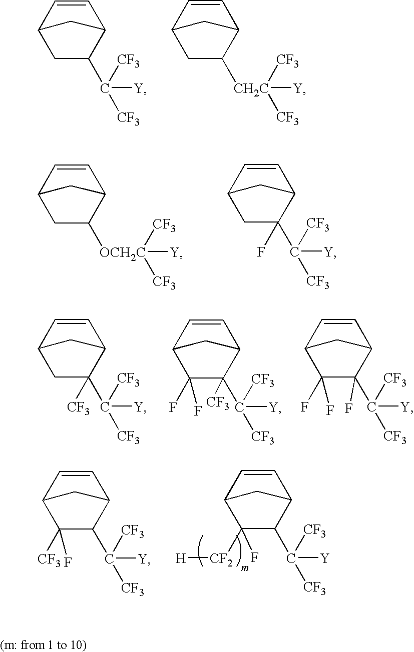

and the like.

Other examples are norbornene derivatives represented by the formula:

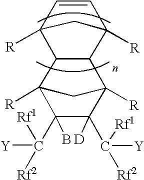

wherein Rf¹ and Rf² are the same or different and each is a fluorine-containing alkyl group having 1 to 10 carbon atoms or a fluorine-containing alkyl group having 1 to 10 carbon atoms and ether bond; B and D are the same or different and each is H, F, Cl, an alkyl group having 1 to 10 carbon atoms or a fluorine-containing alkyl group which has 1 to 10 carbon atoms and may have ether bond; R is H or an alkyl group having 1 to 10 carbon atoms; n is 0 or an integer of from 1 to 5.

Those exemplified monomers (m2-1b) and (m2-2b) having an aliphatic polycyclic structure are preferred particularly as materials for a protective layer for immersion exposing since dry etch resistance, water repellency, water resistance and water-proof property can be imparted to the polymer.

Particularly norbornene derivatives having fluorine atom in its polycyclic structure are preferred from the viewpoint of water repellency, water resistance, water-proof property and transparency.

Also the norbornene derivative (m2-2b) having the hydrophilic functional group Y is preferred since the functional group imparting solubility in a developing solution can be efficiently introduced to the polymer, which is, as a result, advantageous from the viewpoint of transparency and dry etch resistance.

The third of the preferred monomer (m2) is a non-conjugated diene compound which can form an aliphatic ring structure by polymerization and may have fluorine atom. The non-conjugated diene compound can efficiently give a polymer having a structural unit of ring structure in its trunk chain and can improve transparency in a vacuum ultraviolet region like the monomers explained supra.

Preferred examples of the non-conjugated diene compound are, for instance, specific divinyl compounds introducing a monocyclic structure to the trunk chain by ring-forming polymerization which are a compound (m2-1c) having no hydrophilic functional group Y and a compound (m2-2c) having the hydrophilic functional group Y.

Examples thereof are, for instance, diallyl compounds which may have fluorine atom and hydrophilic functional group Y and are represented by the formulae:

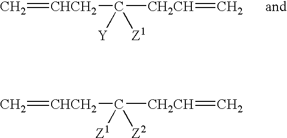

wherein Z¹ and Z² are the same or different and each is hydrogen atom, fluorine atom, a hydrocarbon group which has 1 to 5 carbon atoms and may have ether bond or a fluorine-containing alkyl group which has 1 to 5 carbon atoms and may have ether bond.

By radical ring-forming polymerization of those diallyl compounds, monocyclic structural units represented by:

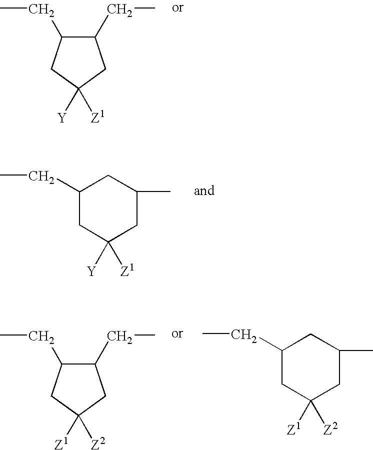

wherein Z¹ and Z² are as defined above, can be formed in the trunk chain.

The fluorine-containing polymer having the hydrophilic functional group Y which is used for the protective layer (L2) can be prepared by introducing a structural unit derived from at least one monomer selected from the monomers (m2-2) having the hydrophilic functional group Y, namely, the above-mentioned monomers (m2-2a), (m2-2b) and (m2-2c) among the monomers (m2) being capable of providing an aliphatic ring structure.

When the monomer (m2-1) having no hydrophilic functional group Y is used as the monomer (m2), a monomer (n1-2) having the hydrophilic functional group Y among the comonomers (n1) may be copolymerized with the monomer (m2) to introduce, in addition to the structural unit (M2), a structural unit (N-1-2) having the hydrophilic functional group Y which is explained infra.

The structural units (N1) and (N) are structural units which may have or may not have the hydrophilic functional group Y and are structural units of the monomers (n1) and (n) which are copolymerizable with the monomers (m1) and (m2) and are mutually copolymerizable with each other. When the structural unit (M2) does not have the hydrophilic functional group Y, the structural unit (N1) has the hydrophilic functional group Y. When the structural unit (N1) does not have the hydrophilic functional group Y, the structural unit (M2) has the hydrophilic functional group Y. The structural unit (N) may have or may not have the hydrophilic functional group Y irrespective of other structural units.

Namely, among the structural units (N1), the structural unit (N1-1) having no hydrophilic functional group Y can be introduced by copolymerizing the monomer (n1-1) having no hydrophilic functional group Y. Also among the structural units (N1), the structural unit (N1-2) having the hydrophilic functional group Y can be introduced by copolymerizing the monomer (n1-2) having the hydrophilic functional group Y.

Examples of the preferred monomer (n1-2) which can introduce the hydrophilic functional group Y to the optional structural unit (N1-2) are copolymerizable ethylenic monomers having the hydrophilic functional group Y.

Preferred examples thereof are acrylic monomers having the hydrophilic functional group Y, fluorine-containing acrylic monomers having the hydrophilic functional group Y, allyl ether monomers having the hydrophilic functional group Y, fluorine-containing allyl ether monomers having the hydrophilic functional group Y, vinyl ether monomers having the hydrophilic functional group Y, fluorine-containing vinyl ether monomers having the hydrophilic functional group Y and the like.

Examples thereof are (meth)acrylic acid, α-fluoroacrylic acid, α-trifluoromethyl acrylic acid, t-butyl (meth)acrylate, t-butyl-α-fluoroacrylate, t-butyl-α-trifluoromethyl acrylate, CH₂═CHCH₂Y,

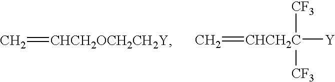

and fluorine-containing ethylenic monomers represented by the formula: CX¹X²=CX³ (CX⁴₂)ₐ(O)_{b}—Rf—Y— wherein X¹ and X² are the same or different and each is H or F; X³ is H, F, CH₃ or CF₃; X⁴ is H, F or CF₃; Rf is a fluorine-containing alkylene group having 1 to 40 carbon atoms or a fluorine-containing alkylene group having 2 to 100 carbon atoms and ether bond; a is 0 or an integer of from 1 to 3; b is 0 or 1.

Among them, fluorine-containing allyl ether compounds represented by the formula:

CH₂═CF—CF₂₀—Rf—Y,

wherein Rf is as defined above, are preferred.

More concretely there are preferably fluorine-containing allyl ether compounds represented by:

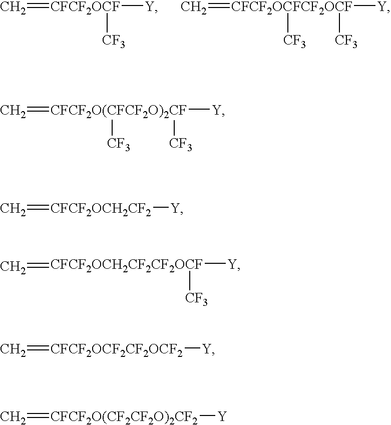

and the like.

Also fluorine-containing vinyl ether compounds represented by the formula:

CF₂═CF—O—Rf—Y,

wherein Rf is as defined above, are preferred.

More concretely there are preferably fluorine-containing vinyl ether compounds represented by:

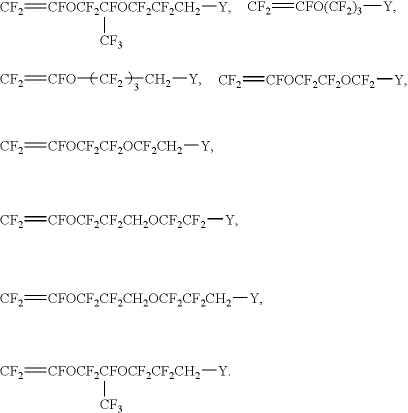

and the like.

Examples of other fluorine-containing ethylenic monomers having the hydrophilic functional group Y are:

### CF₂═CF—CF₂₀—Rf—Y, CF₂═CF—Rf—Y, CH₂═CH—Rf—Y, CH₂═CH—O—Rf—Y

and the like, wherein Rf is as defined above, and more concretely there are:

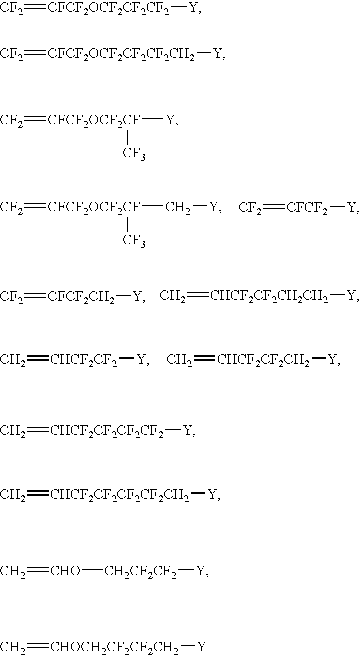

and the like.

Preferred as the monomer (n1-1) giving the optional structural unit (N1-1) are copolymerizable ethylenic monomers having no hydrophilic functional group Y.

Preferred examples thereof are acrylic monomers and fluorine-containing acrylic monomers which are not decomposed with an acid, have ester portion and do not have the hydrophilic functional group Y, allyl ether monomers having no hydrophilic functional group Y, fluorine-containing allyl ether monomers having no hydrophilic functional group Y, vinyl ether monomers having no hydrophilic functional group Y, fluorine-containing vinyl ether monomers having no hydrophilic functional group Y and the like.

Concretely there are monomers such as α-trifluoromethyl acrylic acid ester, α-fluoro acrylic acid ester and (meth)acrylic acid ester represented by:

CX¹¹X¹²═CX¹³COOR,

wherein X¹¹, X¹² and X¹³ are selected from H, F, CH₃ and CF₃; R is a monovalent organic group, in which the ester portion R is bonded to O with a primary or secondary carbon.

Examples of the vinyl ether monomer and fluorine-containing vinyl ether monomer are:

CH₂═CHOR,CF₂═CFORf

and the like, wherein R is a monovalent organic group; Rf is a monovalent fluorine-containing organic group, and more concretely there are:

CH₂═CHOCH₂Rf (Rf is as defined above),CF₂═CFOCF₃,CF₂═CFOCF₂CF₃,

CF₂═CFOCF₂CF₂CF₃

and the like.

Other examples of the fluorine-containing ethylenic monomer having the hydrophilic functional group Y are:

CF₂═CF—CF₂₀—Rf,CF₂═CF—Rf,CH₂═CH—Rf,CH₂═CH—O—Rf

and the like, wherein Rf is as defined above.

The monomer (n) giving the optional structural unit (N) may be the monomer (n-1) having no hydrophilic functional group Y or the monomer (n-2) having the hydrophilic functional group Y as mentioned above. Examples thereof are the monomers (n1-1) and (n1-2) explained supra.

It is preferable from the viewpoint of good dry etch resistance that the fluorine-containing polymer of the formula (M-1) has a structural unit derived from at least one monomer selected from the monomers (m2-2) having the hydrophilic functional group Y, namely, the above-mentioned (m2-2a), (m2-2b) and (m2-2c) among the monomers (m2) being capable of providing an aliphatic ring structure.

There are concretely fluorine-containing polymers represented by the formula (M-2):

-(M1)-(M2-2)-(M2)-(N)— (M-2)

wherein the structural units M1 and M2 are as defined in the above-mentioned formula (M-1); the structural unit M2-2 is a structural unit derived from the monomer (m2-2) which has the hydrophilic functional group Y and can provide an aliphatic ring structure to the polymer trunk chain; the structural unit N is a structural unit derived from a monomer (n) copolymerizable with the monomers (m1), (m2-2) and (m2), and the structural units M1, M2-2, M2 and N are contained in amounts of from 1 to 99% by mole, from 1 to 99% by mole, from 0 to 98% by mole and from 0 to 98% by mole, respectively.

In the formula (M-2), it is preferable that the structural unit (M2-2) is selected from the above-mentioned examples of (m2-2a), (m2-2b) and (m2-2c), and it is particularly preferable from the viewpoint of good dry etch resistance that the structural unit (M2-2) is a structural unit derived from the norbornene derivative (m2-2b).

With respect to the structural units (M1), (M2) and (N), the preferred examples raised in the fluorine-containing polymer of the formula (M-1) can be used similarly (but the examples of the structural units M2 are structural units other than the structural unit M2-2).

In the fluorine-containing polymers of the formula (M-2), when the structural unit (N-2) having the hydrophilic functional group Y is used as the optional structural unit N, examples of the monomer (n-2) are the same as the examples of the above-mentioned ethylenic monomer (n1-2) having the hydrophilic functional group Y.

In the present invention, in addition to the monomers (m1), (m2), (m2-2) and (n1-2), a radically polymerizable monomer may be copolymerized as the optional monomer (n) for the purpose of improving other properties of the obtained fluorine-containing copolymer, for example, mechanical strength and coatability.

Such an optional monomer (n) is selected from the above-mentioned comonomers (n1-2) having the hydrophilic functional group Y and monomers which may have or may not have the hydrophilic functional group Y and are copolymerizable with the monomers (m1), (m2) and (m2-2) constituting the other structural units.

For example, there are monomers mentioned below.

Acrylic Monomers (Excluding Monomers Raised in (n1-2)):

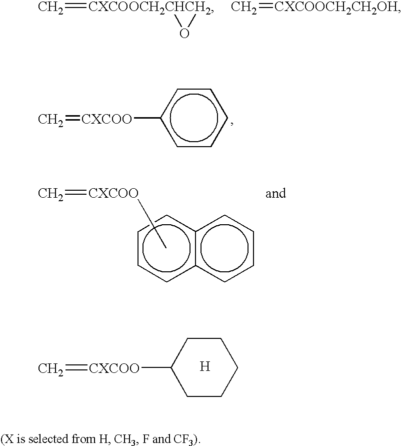

### Styrene Monomers:

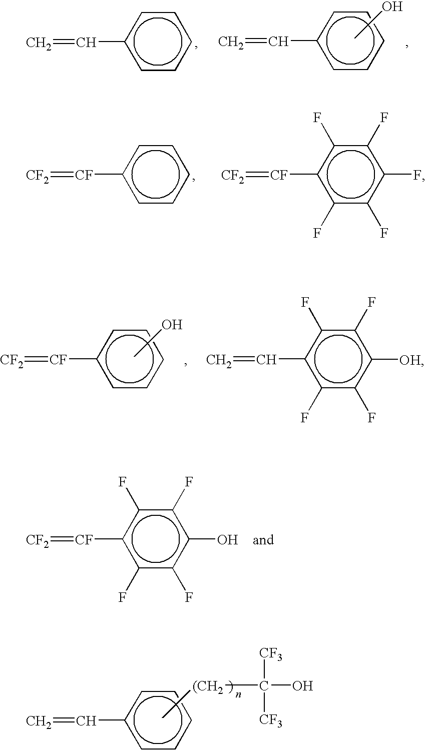

wherein n is 0 or an integer of 1 or 2.

### Ethylene Monomers:

CH₂═CH₂,CH₂═CHCH₃,CH₂═CHCl and the like.

### Maleic Acid Monomers:

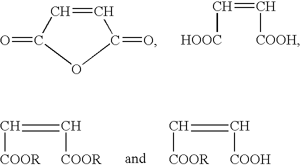

wherein R is a hydrocarbon group having 1 to 20 carbon atoms.

### Allyl Monomers:

CH₂═CHCH₂Cl,CH₂═CHCH₂OH,CH₂═CHCH₂COOH,

CH₂═CHCH₂Br and the like.

### Allyl Ether Monomers:

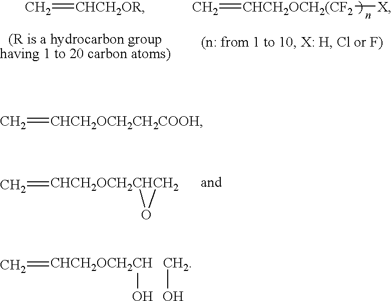

### Other Monomers:

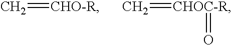

(R is an alkyl group which has 1 to 20 carbon atoms and may be substituted by fluorine)
and more concretely there are:

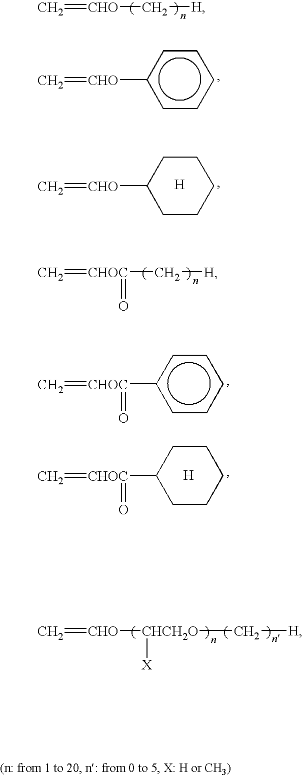

and the like.

In the present invention, a number average molecular weight of the fluorine-containing polymers of the formulae (M-1) and (M-2) is from 1,000 to 100,000, preferably from 2,000 to 50,000, more preferably from 2,000 to 10,000, and a weight average molecular weight thereof is from 2,000 to 200,000, preferably from 3,000 to 50,000, more preferably from 3,000 to 10,000.

The fluorine-containing polymers (A1) having the hydrophilic functional group Y are preferably the following fluorine-containing polymers.

### (I) Fluorine-Containing Polymers Represented by the Formula:

-(M1)-(M2-2a)-

wherein M1 is a structural unit derived from the ethylenic monomer (m1) having 2 or 3 carbon atoms and at least one fluorine atom; M2-2a is a structural unit derived from the monomer (m2-2a) of a monocyclic aliphatic unsaturated hydrocarbon compound which has the hydrophilic functional group Y and may have fluorine atom.

A percent by mole ratio of the structural unit (M1) to (M2-2a) is usually 80/20 to 20/80, preferably 70/30 to 30/70, particularly preferably 60/40 to 40/60.

Examples of the monomers are preferably the above-mentioned examples of the monomers (m1) and (m2-2a).

### (II) Fluorine-Containing Polymers Represented by the Formula:

-(M1)-(M2-2b)-

wherein M1 is as defined above; (M2-2b) is a structural unit derived from the mentioned monomer (m2-2b) which has an aliphatic polycyclic structure and the hydrophilic functional group Y, particularly a structural unit derived from a norbornene derivative.

A percent by mole ratio of the structural unit (M1) to (M2-2b) is usually 80/20 to 20/80, preferably 70/30 to 30/70, particularly preferably 60/40 to 40/60.

Examples of the monomers are preferably the above-mentioned examples of the monomers (m1) and (m2-2b).

Those fluorine-containing polymers of (I) and (II) are excellent in dry etch resistance, water repellency, water resistance, water-proof property and transparency.

### (III) Fluorine-Containing Polymers Represented by the Formula:

-(M1)-(M2-1a)-(N1-2)-

wherein M1 is as defined above; M2-1a is a structural unit derived from the monocyclic monomer (m2-1a) which has no hydrophilic functional group Y and has a polymerizable carbon-carbon unsaturated bond in its ring structure; N1-2 is a structural unit derived from a copolymerizable ethylenic monomer (n1-2) having the hydrophilic functional group Y.

With respect to the proportions of the structural units (M1), (M2-1a) and (N1-2), when (M1)+(M2-1a)+(N1-2) is 100% by mole, {(M1)+(M2-1a)}/(N-1-2) is usually 90/10 to 20/80, preferably 80/20 to 30/70, particularly preferably 70/30 to 40/60.

Examples of the monomers are preferably the above-mentioned examples of the monomers (m1), (m2-1a) and (n1-2).

### (IV) Fluorine-Containing Polymers Represented by the Formula:

(M1)-(M2-1b)-(N1-2)-

wherein M1 and N1-2 are as defined above; M2-1b is a structural unit derived from the monomer (m2-1b) which has an aliphatic polycyclic structure and has no hydrophilic functional group Y, particularly a structural unit derived from a norbornene derivative.

With respect to the proportions of the structural units (M1), (M2-1b) and (N1-2), when (M1)+(M2-1b)+(N1-2) is 100% by mole, {(M1)+(M2-1b)}/(N1-2) is usually 90/10 to 20/80, preferably 80/20 to 30/70, particularly preferably 70/30 to 40/60.

The second of the preferred fluorine-containing polymer (A1) used for the protective layer of the present invention are polymers which have the structural unit (M3) derived from a fluorine-containing ethylenic monomer having the hydrophilic functional group Y. Those polymers are preferred since pure water repellency, pure water resistance, pure water-proof property and solubility in a developing solution can be obtained and are also preferred from the viewpoint of transparency.

Concretely there are fluorine-containing polymers represented by the formula (M-3):

-(M3)-(N2)- (M-3)

wherein the structural unit M3 is a structural unit derived from a fluorine-containing monomer represented by the formula (1):

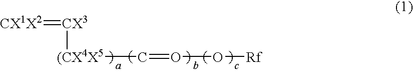

wherein X¹ and X² are the same or different and each is H or F; X³ is H, F, Cl, CH₃ or CF₃; X⁴ and X⁵ are the same or different and each is H or F; Rf is a monovalent organic group in which 1 to 4 hydrophilic functional groups Y are bonded to a fluorine-containing alkyl group having 1 to 40 carbon atoms or a monovalent organic group in which 1 to 4 hydrophilic functional groups Y are bonded to a fluorine-containing alkyl group having 2 to 100 carbon atoms and ether bond; a, b and c are the same or different and each is 0 or 1,
the structural unit N2 is a structural unit derived from a monomer (n2) copolymerizable with the fluorine-containing monomer of the formula (1), and
the structural units M3 and N2 are contained in amounts of from 30 to 100% by mole and from 0 to 70% by mole, respectively.

The fluorine-containing monomer of the formula (1) is characterized by having a monovalent organic group Rf containing a fluorine-containing alkyl group in its side chain and having 1 to 4 hydrophilic functional groups Y bonded to the Rf group. The fluorine-containing monomer of the formula (1) itself contains the hydrophilic functional groups Y and many fluorine atoms, and therefore pure water repellency, pure water resistance, pure water-proof property and solubility in a developing solution can be given to the polymer obtained from such a monomer of the formula (1).

Rf in the fluorine-containing monomer of the formula (1) is preferably a fluorine-containing alkyl group having 1 to 40 carbon atoms in which 1 to 4 hydrophilic functional groups Y are bonded or a fluorine-containing alkyl group having 2 to 100 carbon atoms and ether bond in which 1 to 4 hydrophilic functional groups Y are bonded. Usually Rf having one hydrophilic functional group Y is preferred.

Also preferred as the Rf is a perfluoro alkyl group having 1 to 40 carbon atoms in which hydrophilic functional group is bonded or a perfluoro alkyl group having 2 to 100 carbon atoms and ether bond in which hydrophilic functional group is bonded, because water repellency, water resistance and water-proof property can be further imparted to the polymer.

Preferred examples of the hydrophilic functional group Y are those exemplified above.

The fluorine-containing monomer of the formula (1) is preferred also because polymerizability thereof is good and homopolymerization thereof or copolymerization with other fluorine-containing ethylenic monomer is possible.

The first preferred examples of the fluorine-containing ethylenic monomer of the formula (1) having the hydrophilic functional group Y are monomers represented by the formula (2):

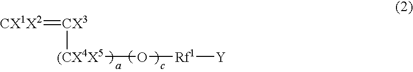

wherein X¹, X², X³, X⁴, X⁵, a and c are as defined in the formula (1); Rf¹ is a divalent fluorine-containing alkylene group having 1 to 40 carbon atoms or a divalent fluorine-containing alkylene group having 2 to 100 carbon atoms and ether bond. The fluorine-containing ethylenic monomers of the formula (2) are preferred because polymerizability thereof is good and homopolymerization or copolymerization with other fluorine-containing ethylenic monomer is possible.

Examples of the fluorine-containing ethylenic monomers of the formula (2) having hydrophilic functional group Y are fluorine-containing ethylenic monomers represented by the formula (2-1):

CH₂═CFCF₂—O—Rf¹—Y (2-1)

wherein Rf¹ is as defined in the formula (2).

The monomers of the formula (2-1) are concretely fluorine-containing ethylenic monomers represented by:

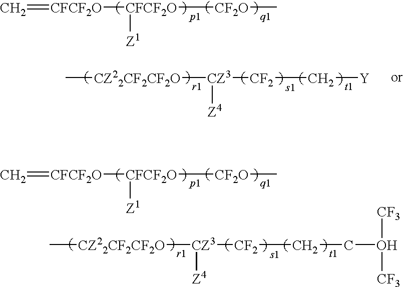

wherein Z¹ is F or CF₃; Z² and Z³ are H or F; Z⁴ is H, F or CF₃; p1+q1+r1 is 0 or an integer of 1 to 10; s1 is 0 or 1; t1 is 0 or an integer of 1 to 5; when both of Z³ and Z⁴ are H, p1+q1+r1+s1 is not 0. Those monomers are preferred because homopolymerizability thereof is excellent and more hydrophilic functional groups Y can be introduced to the fluorine-containing polymer, and as a result, water repellency, water resistance, water-proof property and excellent solubility in a developing solution can be imparted to the protective layer (L2).

Also those monomers have high copolymerizability with fluorine-containing ethylenes such as tetrafluoroethylene and vinylidene fluoride and can impart water repellency, water resistance and water-proof property to the protective layer (L2).

Further preferred examples thereof are:

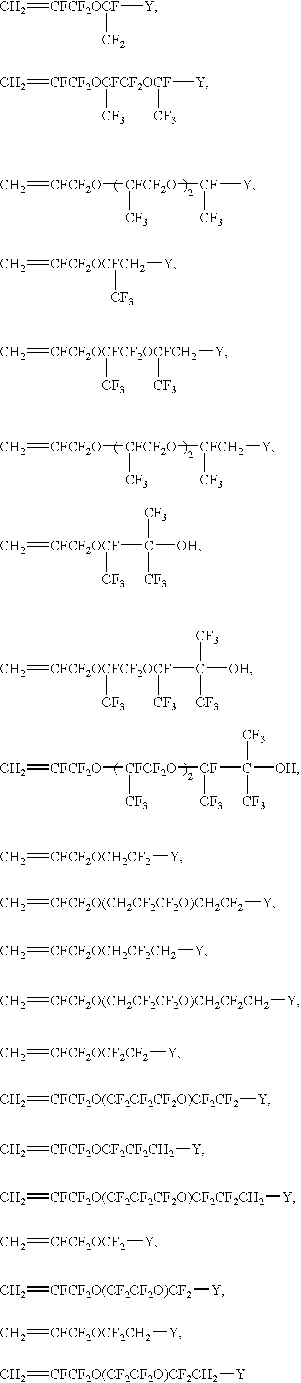

and the like. Among them,

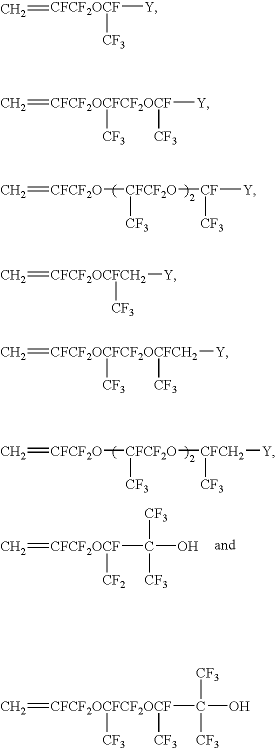

are preferred.

Further examples of the fluorine-containing ethylenic monomer of the formula (2) having the hydrophilic functional group Y are fluorine-containing ethylenic monomers represented by the formula (2-2):

CF₂═CF—O—Rf¹—Y (2-2)

wherein Rf¹ is as defined in the formula (2).

The monomers of the formula (2-2) are concretely fluorine-containing ethylenic monomers represented by:

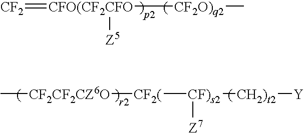

wherein Z⁵ is F or CF₃; Z⁶ is H or F; Z⁷ is H or F; p2+q2+r2 is 0 or an integer of 1 to 10; s2 is 0 or 1; t2 is 0 or an integer of 1 to 5. Those monomers have high copolymerizability with fluorine-containing ethylenes such as tetrafluoroethylene and vinylidene fluoride and can impart water repellency, water resistance and water-proof property to the protective layer (L2).

Further preferred examples of the monomer of the formula (2-2) are:

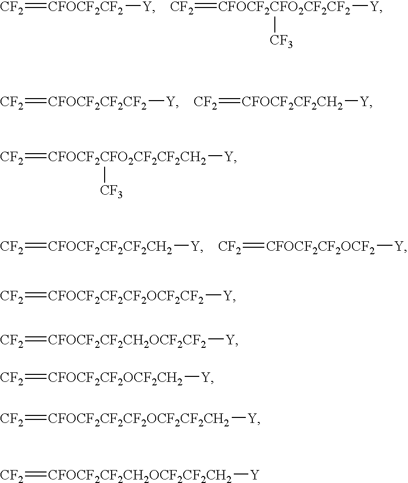

and the like.

Examples of other fluorine-containing ethylenic monomers of the formula (2) having the hydrophilic functional group Y are:

CF₂═CFCF₂—O—Rf¹—Y,CF₂═CF—Rf¹—Y,

CH₂═CH—Rf¹—Y and CH₂═CH—O—Rf¹—Y,

wherein Rf¹ is as defined in the formula (2), and there are concretely:

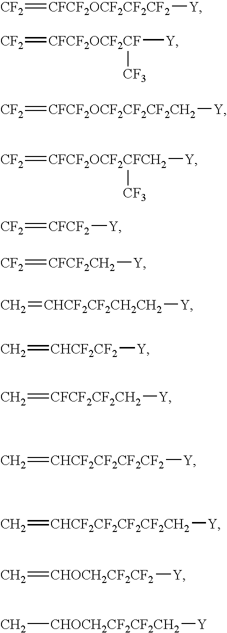

and the like.

Examples of the hydrophilic functional group Y of those fluorine-containing monomers are preferably those exemplified supra, and particularly preferred are —OH and —COOH, especially —COOH.

The second of the preferred fluorine-containing ethylenic monomers of the formula (1) having the hydrophilic functional group Y are fluorine-containing ethylenic monomers represented by the formula (3):

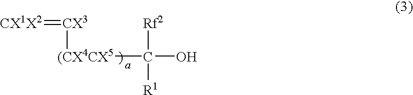

wherein X¹, X², X³, X⁴, X⁵ and a are as defined in the formula (1); Rf² is a fluorine-containing alkyl group which has 1 to 10 carbon atoms and may have ether bond; R¹ is at least one selected from the group consisting of H, hydrocarbon groups having 1 to 10 carbon atoms and fluorine-containing alkyl groups which have 1 to 10 carbon atoms and may have ether bond.

The fluorine-containing polymers obtained therefrom are excellent particularly in transparency and further in water repellency, water resistance and water-proof property, and when used for the protective layer (L2), exhibit effect thereof particularly for resolution at immersion exposing and form of a pattern.

Preferred examples of the fluorine-containing monomers of the formula (3) are concretely:

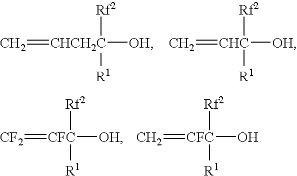

and the like, wherein Rf² and R¹ are as defined in the formula (3), and concretely there are preferably:

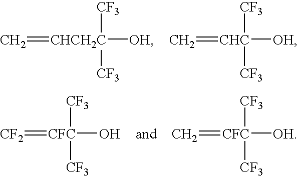

The fluorine-containing polymer of the formula (M-3) to be used for the protective layer (L2) of the present invention may be a homopolymer of the fluorine-containing monomer of the formula (1) having the hydrophilic functional group or a copolymer thereof with other monomer.

In the case of homopolymerizable monomer among the monomers of the formula (1), the homopolymer is more preferred since a dissolution rate of the protective layer (L2) in a developing solution can be increased.

In the case of a copolymer, the structural unit (N2) as a copolymerizable component can be selected optionally, but is preferably so selected as to impart water repellency, water resistance and water-proof property within a range of maintaining solubility in a developing solution. Concretely the structural unit (N2) is selected from structural units derived from fluorine-containing ethylenic monomers.

Particularly preferred are structural units selected from the following structural units (N2-1) and (N2-2).

(N2-1) Structural Unit Derived from a Fluorine-Containing Ethylenic Monomer Having 2 or 3 Carbon Atoms and at Least One Fluorine Atom:

This structural unit N2-1 is preferred because water repellency, water resistance and water-proof property can be effectively imparted and transparency can be improved without lowering solubility in a developing solution, and also because a strength of the protective layer can be improved.

Concretely there are CF₂═CF₂, CF₂—CFCl, CH₂═CF₂, CFH═CH₂, CFH═CF₂, CF₂═CFCF₃, CH₂═CFCF₃, CH₂═CHCF₃ and the like. Among them, preferred are tetrafluoroethylene (CF₂═CF₂), chlorotrifluoroethylene (CF₂═CFCl) and vinylidene fluoride (CH₂═CF₂) from the viewpoint of good copolymerizability and high effects of imparting transparency, water repellency, water resistance and water-proof property.

(N2-2) Structural Unit Derived from a Monomer Represented by the Formula (n2-2):

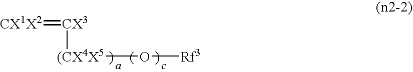

wherein X¹, X², X³, X⁴, X⁵, a and c are as defined in the formula (1); Rf³ is a fluorine-containing alkyl group having 1 to 40 carbon atoms or a fluorine-containing alkyl group having 2 to 100 carbon atoms and ether bond.

This structural unit is preferred since water repellency, water resistance and water-proof property can be effectively imparted and transparency can be improved effectively.

Preferred are:

CH₂═CFCF₂—O—Rf³,CF₂═CF—O—Rf³,CF₂═CFCF₂—O—Rf³,

CF₂═CF—Rf³,CH₂═CH—Rf³,CH₂═CH—O—Rf³

and the like, wherein Rf³ is as defined in the formula (n2-2).

The proportion of each structural unit in the fluorine-containing polymer of the formula (M-3) is optionally selected depending on the above-mentioned preferred fluorine content and the content of hydrophilic functional group. The structural units M3 and N2 are contained in amounts of preferably from 30 to 100% by mole and from 0 to 70% by mole, respectively, further preferably from 40 to 100% by mole and from 0 to 60% by mole, more preferably from 50 to 100% by mole and 0 to 50% by mole, especially preferably from 60 to 100% by mole and from 0 to 40% by mole.

The number average molecular weight of the fluorine-containing polymer of the formula (M-3) is from 1,000 to 1,000,000, preferably from 2,000 to 200,000, more preferably from 3,000 to 100,000, particularly preferably from 5,000 to 50,000.

If the molecular weight is too low, there is a case where there arises a problem that a strength of the protective layer (L2) becomes too low and the fluorine-containing polymer itself permeates into the lower photoresist layer (L1). Also there is a case where film forming property of the protective layer is lowered and formation of a uniform thin film becomes difficult.

The third of the preferred fluorine-containing polymer (A1) to be used for the protective layer (L2) of the present invention is represented by the formula (M-4):

-(M4)-(N3)- (M-4)

wherein the structural unit M4 is a structural unit derived from a fluorine-containing monomer which has —COOH group as the hydrophilic functional group Y and is represented by the formula (4):

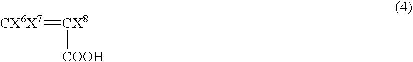

wherein X⁶ and X⁷ are the same or different and each is H or F; X⁸ is H, F, Cl, CH₃ or CF₃; at least one of X⁶, X⁷ and X⁸ contains fluorine atom; the structural unit N3 is a structural unit derived from a monomer (n3) copolymerizable with the fluorine-containing monomer of the formula (4), and
the structural units M4 and N3 are contained in amounts of from 10 to 100% by mole and from 0 to 90% by mole, respectively.

This fluorine-containing polymer contains, as a component for imparting solubility in a developing solution, a structural unit derived from a fluorine-containing acrylic acid which is a fluorine-containing monomer having —COOH group as the hydrophilic functional group Y. This polymer is preferred particularly from the viewpoint of excellent solubility in a developing solution.

Examples of the fluorine-containing monomer of the formula (4) are:

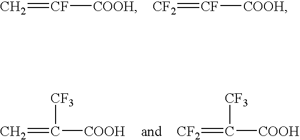

and particularly preferred are:

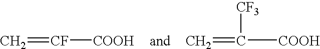

from the viewpoint of goof polymerizability.

The fluorine-containing polymer (M-4) to be used for the protective layer (L2) of the present invention may be a homopolymer of the fluorine-containing monomer of the formula (4), but usually it is preferable that the polymer contains the optional structural unit N3 by copolymerization.

The structural unit N3 of copolymerizable component can be selected optionally, but is preferably so selected as to impart water repellency, water resistance and water-proof property within a range of maintaining solubility in a developing solution. The structural unit N3 is concretely selected from structural units derived from the following fluorine-containing ethylenic monomers.

(N-3-1) Structural Unit Derived from a Fluorine-Containing Acrylate Monomer:

Concretely preferred are structural units derived from fluorine-containing acrylate monomers represented by the formula (n3-1):

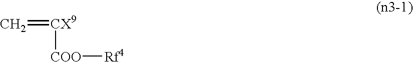

wherein X⁹ is H, F or CH₃; Rf⁴ is a fluorine-containing alkyl group having 1 to 40 carbon atoms or a fluorine-containing alkyl group having 2 to 100 carbon atoms and ether bond. Those monomers are preferred since copolymerizability with the fluorine-containing monomer of the formula (4) is high and water repellency, water resistance and water-proof property can be imparted to the fluorine-containing polymer.

In the fluorine-containing acrylate of the formula (n3-1), examples of Rf⁴ are:

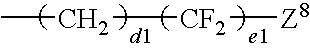

(Z⁸ is H, F or Cl; d1 is an integer of 1 to 4; e1 is an integer of 1 to 10),
—CH(CF₃)₂,

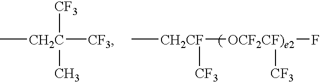

(e2 is an integer of 1 to 5),

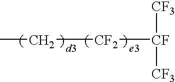

(d3 is an integer of 1 to 4; e3 is an integer of 1 to 10) and the like.
(N-3-2) Structural Unit Derived from a Fluorine-Containing Vinyl Ether Monomer:

Concretely preferred are structural units derived from fluorine-containing vinyl ether represented by the formula (n3-2):

CH₂—CHO—Rf⁵ (n3-2)

wherein Rf⁵ is a fluorine-containing alkyl group having 1 to 40 carbon atoms or a fluorine-containing alkyl group having 2 to 100 carbon atoms and ether bond. Those monomers are preferred since copolymerizability with the fluorine-containing monomer of the formula (4) is high and water repellency, water resistance and water-proof property can be imparted to the fluorine-containing polymer.

Preferred examples of the monomer of the formula (n3-2) are:

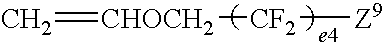

(Z⁹ is H or F; e4 is an integer of 1 to 10),

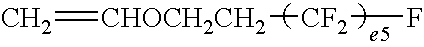

(e5 is an integer of 1 to 10),

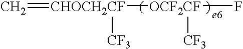

(e6 is an integer of 1 to 10)
and the like.

More concretely there are structural units derived from the following monomers:

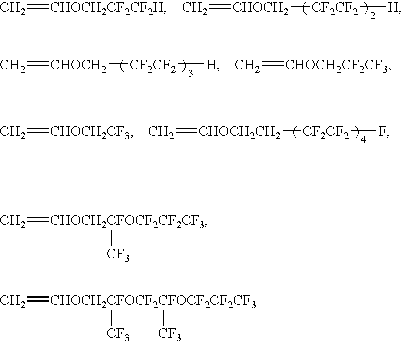

and the like.

Also there are the following structural units (N-3-3) and (N-3-4).

(N-3-3) Structural Unit Derived from a Fluorine-Containing Allyl Ether Represented by the Formula (n3-3):

CH₂═CHCH₂O—Rf⁶ (n3-3)

wherein Rf⁶ is a fluorine-containing alkyl group having 1 to 40 carbon atoms or a fluorine-containing alkyl group having 2 to 100 carbon atoms and ether bond.
(N-3-4) Structural Unit Derived from a Fluorine-Containing Vinyl Monomer Represented by the Formula (n3-4):

CH₂═CH—Rf⁷ (n3-4)

wherein Rf⁷ is a fluorine-containing alkyl group having 1 to 40 carbon atoms or a fluorine-containing alkyl group having 2 to 100 carbon atoms and ether bond.

Those structural units are preferred since water repellency, water resistance and water-proof property can be given to the fluorine-containing polymer.

Examples of the monomers of the formulae (n3-3) and (n3-4) are:

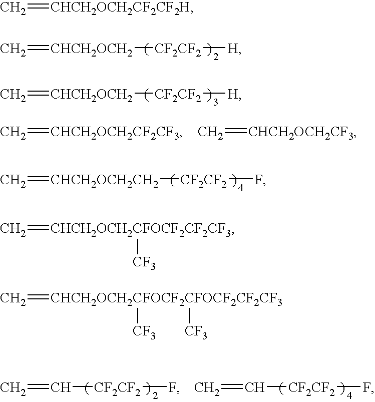

and the like.

The proportion of each structural unit in the fluorine-containing polymer of the formula (M-4) is optionally selected depending on the above-mentioned preferred fluorine content and the content of hydrophilic functional group. The structural units M4 and N3 are contained in amounts of preferably from 10 to 100% by mole and from 0 to 90% by mole, respectively, further preferably from 20 to 80% by mole and from 20 to 80% by mole, more preferably from 30 to 70% by mole and from 30 to 70% by mole, especially preferably from 40 to 60% by mole and from 40 to 60% by mole.

If the proportion of the structural unit M4 is too low, solubility in a developing solution becomes insufficient, and if the proportion of the structural unit M4 is too high, water repellency, water resistance and water-proof property are lowered too much. Therefore the both cases are not preferred.

The number average molecular weight of the fluorine-containing polymer of the formula (M-4) is from 1,000 to 1,000,000, preferably from 2,000 to 200,000, more preferably from 3,000 to 100,000, particularly preferably from 5,000 to 50,000.

If the molecular weight is too low, there is a case where there arises a problem that a strength of the protective layer (L2) becomes too low and the fluorine-containing polymer itself permeates into the lower photoresist layer (L1). Also there is a case where film forming property of the protective layer is lowered, thereby making it difficult to form a uniform thin film.

The fourth of the preferred fluorine-containing polymer (A1) having hydrophilic functional group Y which is used for the protective layer (L2) of the present invention is a fluorine-containing polymer having a structural unit (M5) providing a structure in which a carbon atom linked with the polymer trunk chain through the spacer has the hydrophilic functional group Y as a substituent.

Concretely the fluorine-containing polymer (A1) is represented by the formula (M-5):

-(M1)-(M5)-(N5)- (M-5)

in which the structural unit M1 is as defined supra; the structural unit M5 is a structural unit derived from a monomer (m5) represented by the formula (5):

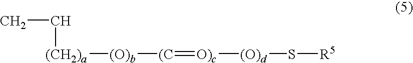

wherein S is a divalent hydrocarbon group having 2 to 40 carbon atoms or a divalent hydrocarbon group having 2 to 100 carbon atoms and ether bond; R⁵ is the hydrophilic functional group Y or a monovalent organic group in which 1 to 4 hydrophilic functional groups Y are bonded to an organic group having 1 to 40 carbon atoms; a, b, c and d are the same or different and each is 0 or 1,
the structural unit N5 is a structural unit derived from a monomer (n5) copolymerizable with the monomers (m1) and (m5),
the structural unit N5 may have the hydrophilic functional group Y and may have fluorine atom, and
the structural units M1, M5 and N5 are contained in amounts of from 1 to 99% by mole, from 1 to 99% by mole and from 0 to 98% by mole, respectively.

The structural unit (M5) providing a structure in which a carbon atom linked with the polymer trunk chain through the spacer group S has the hydrophilic functional group Y as a substituent is obtained usually by polymerizing the monomer (m5) being capable of providing the structural unit (M5). When fluorine atom is not contained in the monomer (m5), it is introduced by copolymerizing with other fluorine-containing monomer, concretely a fluorine-containing ethylenic monomer (m1).

First, in the fluorine-containing polymer of the formula (M-5), preferred examples of the fluorine-containing ethylenic monomer (m1) which provides the structural unit (M1) and can introduce fluorine atom to the polymer trunk chain are the same as the examples of the monomer (m1) raised supra.

Next, in the fluorine-containing polymer of the formula (M-5), the monomer (m5) which can provide the structural unit (M5) is explained below.

The monomer (m5) can introduce, to the polymer, the structural unit (M5) providing a structure in which a carbon atom linked with the polymer trunk chain through the spacer has, as a substituent, the hydrophilic functional group Y giving high solubility in an alkaline developing solution.

(Co)polymerization of this monomer (m5) is preferred since an effect of limiting solubility in pure water by the spacer group S introduced between the hydrophilic functional group Y and the polymer trunk chain can be imparted to the polymer.

It is preferable from the viewpoint of transparency that the spacer group S is a cyclic, branched or linear hydrocarbon group having no aromatic ring structure. Further when the spacer group S contains a linear structure, environmentally responsible property can be imparted to the polymer. Therefore the spacer group S containing a linear structure is preferred in an immersion exposing technology, for the reason that when the protective layer (L2) comes into contact with pure water at exposing, because a water contact angle thereof is large, solubility in pure water is restricted, and subsequently when the protective layer (L2) comes into contact with a developing solution, because a water contact angle becomes small, affinity of the polymer for the developing solution can be enhanced. The spacer group S containing a cyclic structure is preferred because water repellency can be imparted to the polymer and further because in the case of using for the photoresist layer (L3) of the second invention explained infra, dry etch resistance can be imparted to the polymer. The cyclic hydrocarbon group means a hydrocarbon group having a monocyclic or polycyclic aliphatic ring structure, and the hydrocarbon group having the polycyclic aliphatic ring structure is preferred because dry etch resistance can be further enhanced.

It is important that such a spacer group S has a proper length because if its length is short, there is a tendency that its effect is decreased and dissolving and swelling in pure water occur, and if its length is long, there is a tendency that water repellency is increased too much and solubility in a developing solution is lost. Namely, a preferred spacer group S is one having not less than 2 and not more than 40 carbon atoms, more preferably not less than 8 and not more than 20 carbon atoms.

Preferred examples of the monocyclic structure of the spacer group S are, for instance, cyclopropyl structure, cyclobutyl structure, cyclopentyl structure, cyclohexyl structure, cycloheptyl structure, cyclooctyl structure and the like.

Preferred examples of the polycyclic structure are, for instance,

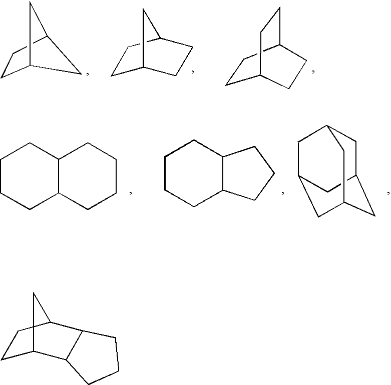

and the like.

The first of the preferred monomer (m5) is a monomer (m5-1) which has a radically polymerizable carbon-carbon unsaturated bond, has the hydrophilic functional group Y, can form a structure in which a spacer portion is introduced between the hydrophilic functional group Y and the polymer trunk chain in the polymer, and has no fluorine atom.

Concretely the monomer (m5-1) is selected from a monocyclic α-olefin monomer (m5-1a) having the hydrophilic functional group Y, a vinyl ether monomer (m5-1b) having the hydrophilic functional group Y and an allyl ether monomer (m5-1c) having the hydrophilic functional group Y.

Those monomers (m5-1a), (m5-1b) and (m5-1c) are preferred since copolymerizability thereof with the fluorine-containing ethylenic monomer (m1) is excellent.

The α-olefin monomer (m5-1a) having the hydrophilic functional group Y is concretely a monomer represented by: CH₂═CH—S—Y⁵,

wherein S is the above-mentioned spacer group; Y⁵ is a hydrophilic functional group.

The hydrophilic functional group Y⁵ is —OH group, —COOH group or —C(CF₃)₂OH group, and since the monomer has S as a spacer, it is preferable that the hydrophilic functional group Y⁵ is —COOH group because solubility of the polymer in a developing solution is good.

The fluorine-containing polymer in which the monomer (m5-1a) containing a spacer group S having not less than 4 carbon atoms is introduced is preferred since water repellency, water resistance and water-proof property can be imparted more to the polymer, and further the fluorine-containing polymer in which the monomer (m5-1a) containing a spacer group S having not less than 8 carbon atoms is introduced is preferred as a material for a protective layer for immersion exposing.

Preferred examples of the α-olefin monomer (m5-1a) having the hydrophilic functional group Y are:

CH₂═CH—(CH₂)ₙ—Y,

wherein n is an integer of 2 to 20, since environmentally responsible property can be imparted to the polymer.

Examples of the vinyl ether monomer (m5-1b) having the hydrophilic functional group Y are monomers of:

CH₂═CH—O—S—Y⁵,

wherein S and Y⁵ are as defined in the above-mentioned (m5-1a).

Preferred examples of the vinyl ether monomer (m5-1b) having the hydrophilic functional group Y are:

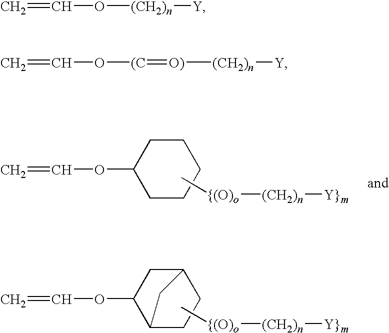

wherein n is an integer of 2 to 20; m is an integer of 1 to 4; o is 0 or 1.

Examples of the allyl ether monomer (m5-1c) having the hydrophilic functional group Y are monomers of:

CH₂═CH—CH₂—O—S—Y⁵,

wherein S and Y⁵ are as defined in the above-mentioned (m5-1a).

Preferred examples thereof are:

CH₂═CH—CH₂—O—(CH₂)ₙ—Y and CH₂═CH—CH₂—O—(C═O)—(CH₂)ₙ—Y,

wherein n is an integer of 2 to 20.

The monomer (n5) copolymerizable with the monomer (m1) and monomer (m5) may contain or may not contain the hydrophilic functional group Y, and from the point that water repellency, water resistance and water-proof property can be imparted to the fluorine-containing polymer, the monomer containing no hydrophilic functional group Y is preferred. Preferred examples of the monomer (n5) containing no hydrophilic functional group Y are the above-mentioned monomer (m2-1), acrylic (or methacrylic) monomer, fluorine-containing acrylic (or methacrylic) monomer, allyl ether monomer, fluorine-containing allyl ether monomer, vinyl ether monomer and fluorine-containing vinyl ether monomer, from the viewpoint of good polymerizability with the monomer (m1). Among them, fluorine-containing monomers are preferred since water repellency, water resistance and water-proof property can be effectively imparted to the polymer by an effect of fluorine atoms contained therein. Also monomers having an aliphatic ring structure are preferred since water repellency, water resistance and water-proof property can be effectively imparted more to the polymer.

Examples of the monomer (n5) are the monomer (n1-1) having no hydrophilic functional group Y among the examples of the monomer (n1) raised supra, and the above-mentioned monomers (m2-1), (n2-2), (n2-3), (n2-4), (n3-1) and (n3-2).

Further among the monomers (n3-1), preferred are:

CH₂═CHCOO—(CH₂)ₙ(CF₂)ₘ—X,CH₂═C(CH₃)COO—(CH₂)ₙ—(CF₂)ₘ—X,

CH₂═C(CF₃)COO—(CH₂)ₙ(CF₂)ₘ—X,CH₂═CFCOO—(CH₂)ₙ—(CF₂)ₘ—X

and the like, wherein n is 1 or 2; m is an integer of 2 to 20; X is H or F, from the point that water repellency, water resistance and water-proof property can be effectively imparted more to the polymer.

The proportions of each structural unit in the fluorine-containing polymer of the formula (M-5) are optionally selected depending on the above-mentioned preferred fluorine content and the content of hydrophilic functional group. The structural units M1, M5 and N5 are contained in amounts of preferably from 10 to 99% by mole, from 10 to 99% by mole and from 0 to 80% by mole, respectively, further preferably from 30 to 70% by mole, from 30 to 70% by mole and from 0 to 30% by mole, more preferably from 40 to 60% by mole, from 40 to 60% by mole and from 0 to 20% by mole, particularly preferably from 45 to 55% by mole, from 45 to 55% by mole and from 0 to 10% by mole.

If the proportion of the structural unit M5 is too low, solubility in a developing solution becomes insufficient, and if the proportion of the structural unit M5 is too high, water repellency, water resistance and water-proof property are lowered too much. Accordingly the both cases are not preferred.

The number average molecular weight of the fluorine-containing polymer of the formula (M-5) obtained in the present invention is from 1,000 to 100,000, preferably from 2,000 to 50,000, more preferably from 2,000 to 10,000, and the weight average molecular weight thereof is from 2,000 to 200,000, preferably from 3,000 to 50,000, more preferably from 3,000 to 10,000.

If the molecular weight is too low, there is a case where there arises a problem that a strength of the protective layer (L2) becomes too small and the fluorine-containing polymer itself permeates into the lower photoresist layer (L1). Also there is a case where film forming property of the protective layer is lowered, thereby making it difficult to form a uniform thin film.

The fifth of the preferred fluorine-containing polymer (A1) having the hydrophilic functional group Y which is used for the protective layer (L2) of the first laminated resist of the present invention is a fluorine-containing polymer which has an aliphatic ring structure in its trunk chain, has a structural unit (M6) providing a structure in which a carbon atom linked with the polymer trunk chain through the spacer group S has the hydrophilic functional group Y as a substituent, and is represented by the formula (M-6):

-(M1)-(M6)-(N)- (M-6)

in which the structural unit M1 and N are as defined in the formula (M-1); the structural unit M6 is a structural unit derived from a monomer (m6) which provides an aliphatic ring structure in the polymer trunk chain and can provide a structure in which a carbon atom linked with the polymer trunk chain through the spacer group S has the hydrophilic functional group Y as a substituent, and
the structural units M1, M6 and N are contained in amounts of from 1 to 99% by mole, from 1 to 99% by mole and from 0 to 98% by mole, respectively. The spacer group S is a divalent hydrocarbon group having 2 to 40 carbon atoms or a divalent hydrocarbon group having 2 to 100 carbon atoms and ether bond.

First, in the fluorine-containing polymer of the formula (M-6), the monomer (m6) which can provide an aliphatic ring structure in the polymer trunk chain and a structural unit (M6) of a structure in which a carbon atom linked with the polymer trunk chain through the spacer group S has the hydrophilic functional group Y as a substituent is explained below.

The monomer (m6) can introduce, to the polymer trunk chain, the structural unit (M6) of aliphatic ring structure which enhances dry etch resistance when used for the photoresist layer (L3) of the second of the present invention explained infra. It is preferable from the viewpoint of good transparency that the spacer group S in the monomer (m6) is a cyclic, branched or linear hydrocarbon group having no aromatic ring structure. Further when the spacer group S contains a linear structure, environmentally responsible property can be imparted to the polymer. Therefore the spacer group S containing a linear structure is preferred in an immersion exposing technology, for the reason that when the protective layer (L2) comes into contact with pure water at exposing, because a water contact angle thereof is large, solubility in pure water is restricted, and subsequently when the protective layer (L2) comes into contact with a developing solution, because a water contact angle thereof becomes small, affinity of the polymer for the developing solution can be enhanced. The spacer group S containing a cyclic structure is preferred because in the case of using for the photoresist layer (L3) of the second invention explained infra, dry etch resistance can be imparted to the polymer and also water repellency can be imparted to the polymer.

It is important that such a spacer group S has a proper length because if its length is short, there is a tendency that its effect is decreased and dissolving and swelling in pure water occur, and if its length is long, there is a tendency that water repellency is increased too much and solubility in a developing solution is lost. Namely, a preferred spacer group S is one having not less than 2 and not more than 40 carbon atoms since water repellency, water resistance and water-proof property are imparted more, further preferably not less than 4 and not more than 10 carbon atoms because of its excellent protecting action at immersion exposing.

Further it is preferable from the viewpoint of good transparency that the spacer group S is a cyclic, branched or linear hydrocarbon group having no aromatic ring structure. Also it is preferable from the viewpoint of enhancing dry etch resistance that the spacer group S is a cyclic hydrocarbon group. The cyclic hydrocarbon group means an organic group having a monocyclic or polycyclic aliphatic ring structure, and the hydrocarbon group having the polycyclic aliphatic ring structure is preferred because dry etch resistance can be further enhanced.

Preferred examples of the monocyclic structure are, for instance, cyclopropyl structure, cyclobutyl structure, cyclopentyl structure, cyclohexyl structure, cycloheptyl structure, cyclooctyl structure and the like.

Preferred examples of the polycyclic structure are, for instance,

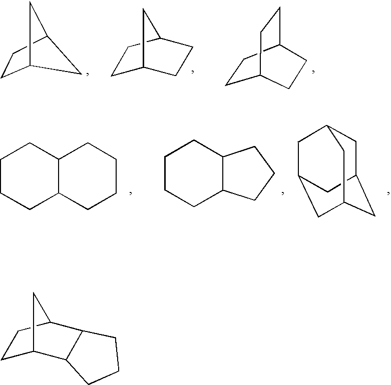

and the like.

The monomer (m6) may be selected from unsaturated cyclic compounds having a radically polymerizable carbon-carbon unsaturated bond in its ring structure and also may be selected from non-conjugated diene compounds which can form a ring structure in the trunk chain by ring-forming polymerization.

Also the monomer (m6) has the hydrophilic functional group Y, and by (co)polymerizing this monomer (m6), a polymer having a monocyclic or polycyclic aliphatic ring structure unit in its trunk chain can be obtained.

Preferred examples of the monocyclic or polycyclic structure in the polymer trunk chain which is given by the monomer (m6) are, for instance, cyclopropyl structure, cyclobutyl structure, cyclopentyl structure, cyclohexyl structure, cycloheptyl structure, cyclooctyl structure,

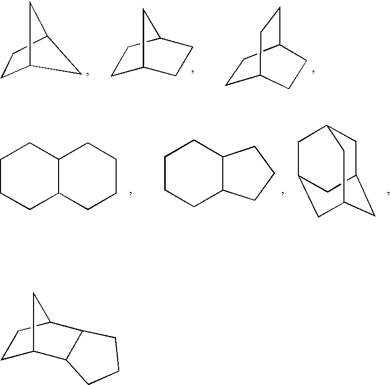

and the like, and the structural units provided by the monomer (m6) are structural units of derivatives thereof, in which a part of hydrogen atoms thereof are replaced by —S—R group.

Preferred monomers (m6) are monomers which have a radically polymerizable carbon-carbon unsaturated bond, can form a monocyclic or polycyclic structure in the polymer trunk chain and also has the spacer group S and the hydrophilic functional group Y.

Namely, the monomer (m6) is selected from a monomer (m6-1) of a polycyclic aliphatic unsaturated hydrocarbon compound having the hydrophilic functional group Y, a monomer (m6-2) of a monocyclic aliphatic unsaturated hydrocarbon compound having the hydrophilic functional group Y and a monomer (m6-3) having the hydrophilic functional group Y which is a non-conjugated diene compound mentioned infra which can be subjected to ring-forming polymerization.

It is preferable, from the viewpoint of high polymerizability with the monomer (m1), that the monomer (m6-1) which is the first preferred monomer (m6) is a norbornene derivative which can provide a structure in which a carbon atom linked with the polymer trunk chain through the spacer group S has the hydrophilic functional group Y as a substituent. Further from the viewpoint of dry etch resistance, it is preferable that the monomer (m6-1) has a structure containing no fluorine atom in the norbornene skeleton.

Concretely the monomer (m6-1) is preferably one represented by the formula:

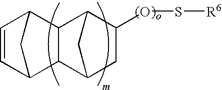

wherein S is a spacer group which is a divalent hydrocarbon group having 2 to 40 carbon atoms or a divalent hydrocarbon group having 2 to 100 carbon atoms and ether bond; R⁶ is the hydrophilic functional group Y or a monovalent organic group in which 1 to 4 hydrophilic functional groups Y are bonded to an organic group having 1 to 40 carbon atoms; m and o are 0 or 1. When one hydrophilic functional group Y is contained in the monomer (m6-1), it is preferable that Y is COOH group from the viewpoint of solubility of the polymer in a developing solution.

Further it is preferable that the monomer (m6-1) is one represented by the formula:

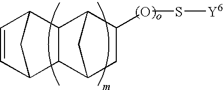

wherein S is the above-mentioned spacer group; m and o are 0 or 1.

The hydrophilic functional group Y⁶ is —OH group, —COOH group or —C(CF₃)₂OH group. Since there is the spacer group S, —COOH group is preferred from the viewpoint of good solubility of the polymer in a developing solution.

Concretely it is preferable that the monomer (m6-1) is one represented by the formula:

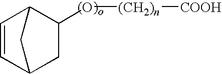

wherein o is 0 or 1; n is an integer of 2 to 20, since a proper environmentally responsible property can be imparted to the polymer. Further it is preferable that n is not less than 4 and not more than 10 since a necessary glass transition temperature of the polymer can be maintained.

Next, explained below is the second preferred monomer (m6) which is the monomer (m6-2) of a monocyclic aliphatic unsaturated hydrocarbon compound having the hydrophilic functional group Y. It is preferable that the monocyclic monomer (m6-2) is an unsaturated hydrocarbon compound of three- to eight-membered ring structure which may have ether bond in its ring structure. Also the monomer (m6-2) may be a monomer in which a part or the whole of hydrogen atoms are replaced by fluorine atoms like the monomers explained supra.

Examples of the monocyclic monomer (m6-2) having the hydrophilic functional group Y are:

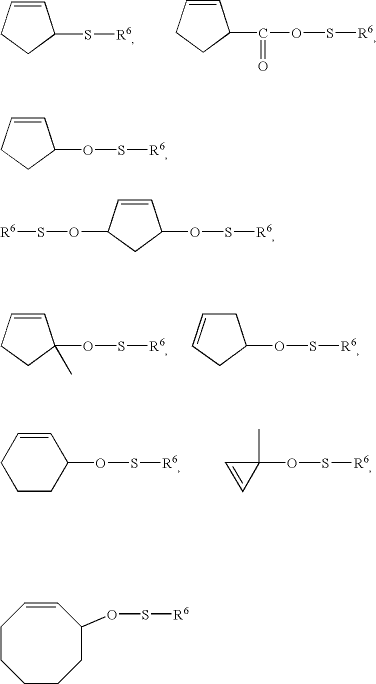

and the like, wherein S is a spacer group; R⁶ is as defined above.

The third preferred monomer (m6) is a non-conjugated diene compound which can form an aliphatic ring structure by polymerization and has the spacer group S and the hydrophilic functional group Y. The non-conjugated diene compound can efficiently provide a polymer having a structural unit of ring structure in its trunk chain and can improve transparency in a vacuum ultraviolet region as mentioned supra.

Preferred examples of the non-conjugated diene compound (m6-3) are, for instance, specific diene compounds which provide a monocyclic structure in the polymer trunk chain by ring-forming polymerization.

Example thereof is a diallyl compound which has the spacer group S and the hydrophilic functional group Y and is represented by the formula:

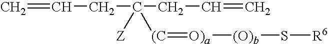

wherein S and R⁶ are as defined above; Z is hydrogen atom or a hydrocarbon group which has 1 to 5 carbon atoms and may have ether bond; a and b are 0 or 1.

By radical ring-forming polymerization of this diallyl compound, a monocyclic structural unit represented by:

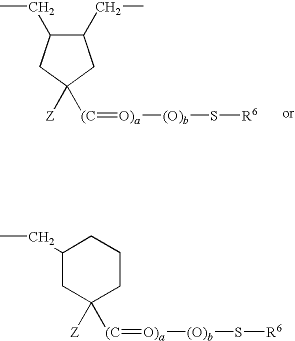

wherein S and R⁶ are as defined above; Z is hydrogen atom or a hydrocarbon group which has 1 to 5 carbon atoms and may have ether bond; a and b are 0 or 1, can be formed in the polymer trunk chain.

In the fluorine-containing polymer of the formula (M-6), a monomer (n-2) which has the hydrophilic functional group Y and is copolymerizable with (m1) and (m6) may be copolymerized for the purpose of improving solubility in a developing solution. It is preferable that the monomer (n-2) is selected from the monomers exemplified in the formula (M-1).

In the present invention, in addition to the monomers (m1), (m6) and (n-2) or instead of the monomer (n-2), a radically polymerizable monomer may be copolymerized as an optional monomer (n-1) providing an optional structural unit (N) and having no hydrophilic functional group Y for the purpose of improving other properties of the obtained fluorine-containing copolymer such as a mechanical strength and coatability.

Preferred examples of such an optional monomer (n-1) are those selected from the monomers exemplified in the formula (M-1).

A number average molecular weight of the fluorine-containing polymer of the formula (M-6) of the present invention is from 1,000 to 100,000, preferably from 2,000 to 50,000, more preferably from 2,000 to 10,000, and a weight average molecular weight thereof is from 2,000 to 200,000, preferably from 3,000 to 50,000, more preferably from 3,000 to 10,000.

Preferred examples of the fluorine-containing polymer (A1) to be used for the protective layer (L2) of the present invention are fluorine-containing polymers represented by the following formulae (M-3-1), (M-3-2) and (M-4-1).

Fluorine-containing polymers having a number average molecular weight of from 1,000 to 200,000 and represented by the formula (M-3-1):

-(M3-1) (M-3-1)

in which the structural unit M3-1 is a structural unit derived from a monomer represented by the formula (2-1):

CH₂═CFCF₂—O—Rf¹—Y (2-1)

wherein Rf¹ is as defined in the formula (2). Namely, those polymers are fluorine-containing allyl ether homopolymers containing at least one monomer selected from the monomers of the formula (2-1). Those polymers have a high fluorine content and a high content of hydrophilic group and therefore are preferred since water repellency, water resistance, water-proof property and solubility in a developing solution are excellent. Fluorine-containing polymers having a number average molecular weight of from 1,000 to 200,000 and represented by the formula (M-3-2):

(M3-2)-(N2-1)- (M-3-2)

in which the structural unit M3-2 is a structural unit derived from a monomer represented by the formula (3):

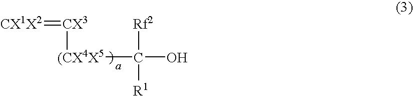

wherein X¹, X², X³, X⁴, X⁵, Rf², R¹ and a are as defined in the formula (3) explained supra,
the structural unit N2-1 is a structural unit derived from a fluorine-containing ethylenic monomer having 2 or 3 carbon atoms and at least one fluorine atom, and
the structural units M3-2 and N2-1 are contained in amounts of from 30 to 70% by mole and from 30 to 70% by mole, respectively.

Preferred examples of the monomer for the structural unit M3-2 are the same as exemplified supra in the formula (3), and particularly preferred as the monomer for the structural unit M3-2 are monomers selected from those represented by:

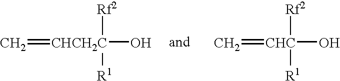

wherein Rf² and R¹ are as defined in the formula (3).

The structural unit N2-1 is preferably a structural unit derived from the monomer selected from tetrafluoroethylene and chlorotrifluoroethylene.

Those monomers are preferred since transparency to light in an ultraviolet region is high and water repellency, water resistance and water-proof property can be imparted to the polymer.

Fluorine-Containing Polymers Having a Number Average Molecular Weight of from 1,000 to 200,000 and Represented by the Formula (M-4-1):

-(M4)-(N-3-2)- (M-4-1)

in which the structural unit M4 is a structural unit derived from a monomer represented by the formula (4):

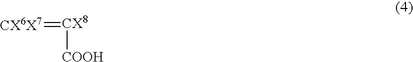

wherein X⁶, X⁷ and X⁸ are as defined in the formula (4) explained supra, the structural unit N3-2 is a structural unit derived from a monomer represented by the formula (n3-2):

CH₂═CHO—Rf⁵ (n3-2)

wherein Rf⁵ is as defined in the formula (n3-2) explained supra, and the structural units M4 and N3-2 are contained in amounts of from 30 to 70% by mole and from 30 to 70% by mole, respectively.

Preferred examples of the monomer for the structural unit M4 are the same as exemplified supra in the formula (4), and the monomers represented by:

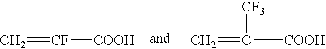

are particularly preferred.

Preferred examples of the monomer for the structural unit N3-2 are the same as exemplified supra in the formula (n3-2), and particularly preferred as the monomer for the structural unit N3-2 are monomers represented by:

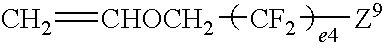

wherein Z⁹ is H or F; e4 is an integer of 1 to 10.

Those polymers are preferred especially because of excellent solubility in a developing solution.

In the first laminated resist of the present invention, the protective layer (L2) is formed on the previously formed photoresist layer (L1) by applying the coating composition containing the above-mentioned fluorine-containing polymer (A1).

The coating composition for forming the protective layer (L2) contains the fluorine-containing polymer (A1) having the hydrophilic functional group Y and the solvent (C1).

It is preferable that the solvent (C1) is selected from solvents which dissolve the fluorine-containing polymer (A1) homogeneously, and a solvent having good film forming property is optionally selected and utilized.

Preferred examples of the solvent are cellosolve solvent, ester solvent, propylene glycol solvent, ketone solvent, aromatic hydrocarbon solvent, alcohol solvent, water and solvent mixture thereof. Further fluorine-containing solvents such as fluorine-containing hydrocarbon solvents such as CH₃CCl₂F (HCFC-141b) and fluorine-containing alcohols may be used together for enhancing solubility of the fluorine-containing polymer (A1) and film forming property.

It is preferable that the solvent is selected from solvents which do not re-dissolve the lower photoresist film (L1) previously formed. From this point of view, water and/or alcohols are preferred.

An amount of the solvent (C1) is selected depending on kind of solids to be dissolved, kind of a substrate to be coated, an intended coating thickness and the like. From the viewpoint of easy coating, it is preferable that the solvent is used in such an amount that the concentration of the whole solids of the coating composition is from 0.5 to 70% by weight, preferably from 1 to 50% by weight.

Among the solvents (C1), water is not limited particularly. Preferred are distilled water, ion exchange water, water subjected to filtration and water subjected to various adsorption treatments to remove organic impurities and metal ion.

Alcohols are optionally selected from those which do not re-dissolve the lower photoresist layer (L1), depending on kind of the photoresist layer (L1). Generally lower alcohols are preferred, and concretely methanol, ethanol, isopropanol, n-propanol and the like are preferred.

In addition to the solvent (C1), a water soluble organic solvent may be used together for the purpose of improving coatability, etc. to such an extent not to re-dissolve the photoresist layer (L1).

A water soluble organic solvent is not limited particularly as far as it dissolves in an amount of not less than 1% by mass based on water. Preferred examples thereof are, for instance, ketones such as acetone and methyl ethyl ketone; esters of acetic acids such as methyl acetate and ethyl acetate; polar solvents such as dimethylformamide, dimethyl sulfoxide, methyl cellosolve, cellosolve acetate, butyl cellosolve, butyl carbitol and carbitol acetate; and the like.

An adding amount of the water soluble organic solvent to be added in addition to water or alcohol is from 0.1 to 50% by mass, preferably from 0.5 to 30% by mass, more preferably from 1 to 20% by mass, particularly preferably from 1 to 10% by mass based on the total amount of the solvent (C1).

To the coating composition forming the protective layer (L2) of the present invention may be added, as case demands, at least one selected from basic substances, for example, ammonia and organic amines. In this case, there is a case where an acidic OH group having a pKa value of not more than 11 becomes a hydrophilic derivative moiety, for example, in the form of ammonium salt, amine salt or the like in the coating composition.

Especially when the hydrophilic functional group Y in the fluorine-containing polymer (A1) is —COOH or —SO₃H, the addition of the basic substance is effective for enhancing water solubility and solubility in a developing solution and also for maintaining reproducibility of a dissolution rate in a developing solution. Also it is effective for adjusting the pH value of the coating composition to be within an optimum range.

With respect to the organic amines, preferred are water soluble organic amine compounds. Preferred examples thereof are, for instance, primary amines such as methylamine, ethylamine and propylamine; secondary amines such as dimethylamine and diethylamine; tertiary amines such as trimethylamine, triethylamine and pyridine; hydroxylamines such as monoethanolamine, propanolamine, diethanolamine, triethanolamine and tris(hydroxymethyl)aminomethane; quaternary ammonium compounds such as tetramethylammonium hydroxide, tetraethylammonium hydroxide, tetrapropylammonium hydroxide and tetrabutylammonium hydroxide; and the like.

Among them, from the point of increasing a dissolution rate in a developing solution, preferred are hydroxylamines such as monoethanolamine, propanolamine, diethanolamine, triethanolamine and tris(hydroxymethyl)aminomethane, and particularly preferred is monoethanolamine.

Also to the coating composition forming the protective layer (L2) of the present invention may be added, as case demands, a defoaming agent, light absorbing agent, storage stabilizer, antiseptic agent, adhesion promoter, photoacid generator and the like.

In the coating composition forming the protective layer (L2) of the present invention, the content of the fluorine-containing polymer (A1) having hydrophilic group varies depending on kind and molecular weight of the polymer, kind and amount of additives, kind of a solvent and the like, and is optionally selected so that a suitable viscosity being capable of forming a thin coating film is obtained. For example, the content of the polymer is from 0.1 to 50% by mass, preferably from 0.5 to 30% by mass, more preferably from 1 to 20% by mass, particularly preferably from 2 to 10% by mass based on the whole coating composition.

The coating composition is applied on the photoresist layer (L1) to form the protective layer (L2) as an outermost layer of the laminated resist.

For the application, conventional methods are adopted. Examples of the suitable methods are rotary coating method, cast coating method, roll coating method and the like, and particularly a rotary coating method (spin coating method) is preferred.

A thickness of the protective layer varies depending on kind of the fluorine-containing polymer (A1) having hydrophilic group, immersion exposing conditions, contact time with water and the like, and is optionally selected. The thickness is usually from 1 to 500 nm, preferably from 10 to 300 nm, more preferably from 20 to 200 nm, particularly preferably from 30 to 100 nm.

Since transparency of the fluorine-containing polymer (A1) of the present invention is high, a fine pattern can be formed even if the thickness of the protective layer is thick.

In the laminated resist of the present invention, the photoresist layer (L1) is a layer formed using a conventional photoresist composition on a substrate such as a wafer mentioned infra.

The photoresist layer (L1) is a layer obtained by forming a film of, for example, a positive photoresist containing, as main components, a novolak resin and diazonaphthoquinone (g-line or i-line lithography), a chemically amplifying positive or negative resist prepared using polyhydroxystyrene as a binder resin (KrF lithography), a chemically amplifying positive photoresist prepared using an acrylic polymer having an alicyclic structure in its side chain or an alicyclic polymer having a polynorbornene structure (ArF lithography) or the like.

A thickness of the photoresist layer (L1) varies depending on kind and purpose of a device to be produced, conditions for etching and the like for production thereof and kind of the resist layer (degrees of transparency and dry etch resistance), and is optionally selected. The thickness is usually from 10 to 5,000 nm, preferably from 50 to 1,000 nm, more preferably from 100 to 500 nm.

The protective layer (L2) of the present invention is excellent in at least one of water repellency, water resistance and water-proof property at immersion exposing using pure water, as compared with conventional resists having a photoresist layer as an outermost layer or an antireflection layer as an outermost layer. Therefore the protective layer can be preferably applied especially to an immersion photolithography process using a chemically amplifying positive photoresist (ArF lithography) prepared from an acrylic polymer having an alicyclic structure in its side chain or an alicyclic polymer having a polynorbornene structure, and purposes of obtaining precise pattern form, high dimensional accuracy of a pattern and reproducibility thereof are accomplished effectively.

Examples of the substrate in the first laminated resist of the present invention are, for instance, a silicon wafer; a glass substrate; a silicon wafer or glass substrate provided with an organic or inorganic antireflection film; a silicon wafer which has steps and is provided with various insulating films, electrode and wiring on a surface thereof; a mask blank; a semiconductor wafer of III-V group compound such as GaAs or AlGaAs and a semiconductor wafer of II-VI group compound; a piezoelectric wafer of crystal, quartz or lithium tantalate and the like.

The formation of the resist is not limited to the case of forming the resist on a so-called substrate. The resist may also be formed on a specific layer such as an electrically conductive film, insulating film or the like which is formed on the substrate. Also it is possible to form an antireflection film (lower antireflection layer), for example, DUV-30, DUV-32, DUV-42 and DUV44 available from Brewer Science Co., Ltd. on the substrate. The substrate may be treated with an adhesion improver.

Next, an example of the method of producing the first laminated resist of the present invention, namely the method of forming the laminated resist by providing the protective layer (L2) on the photoresist layer (L1) and further the method of forming a fine pattern by immersion exposing using the laminated photoresist is explained below by means of the drawing.

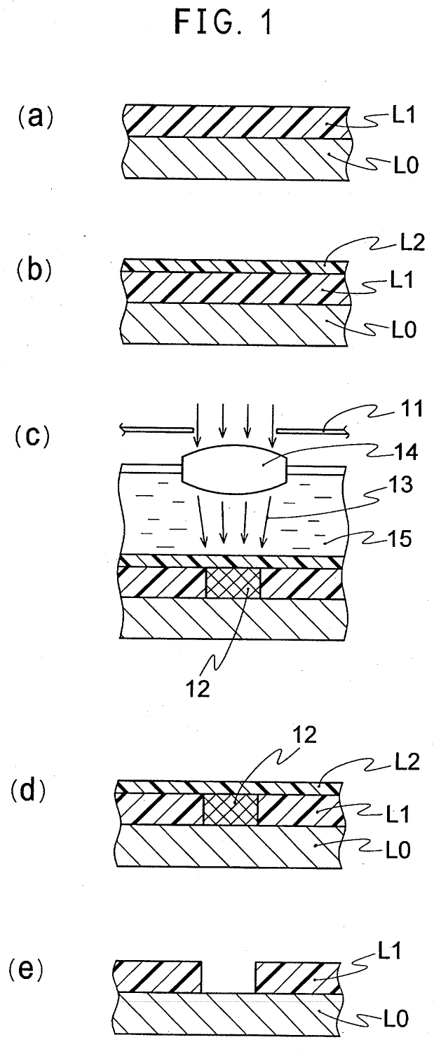

FIG. 1 is a diagrammatic view for explaining each step (a) to (e) of the method of forming the first laminated resist of the present invention and the method of forming a fine pattern by immersion exposing.

### (a) A Step for Forming the Photoresist Layer (L1):

First, as shown in FIG. 1(a), the photoresist composition is coated on a substrate (L0) by a rotary coating method or the like in a coating thickness of from 10 to 5,000 nm, preferably from 50 to 1,000 nm, more preferably from 100 to 500 nm.

Next, pre-baking treatment is carried out at a pre-determined temperature of not more than 150° C., preferably from 800 to 130° C. to form the photoresist layer (L1).

(b) A step for Forming the Protective Layer (L2):

As shown in FIG. 1(b), on the dried photoresist layer (L1) is applied the coating composition containing the fluorine-containing polymer (A1) by a rotary coating method or the like. Then pre-baking is carried out, as case demands, to form the protective layer (L2).

The pre-baking conditions are optionally selected for the purpose of evaporating the residual solvent (C1) in the protective layer (L2) and further forming a uniform thin film. For example, the pre-baking temperature is selected within a range of from room temperature to 150° C., preferably from 400 to 120° C., more preferably from 60° to 100° C.

### (c) A Step for Immersion Exposing:

Subsequently as shown in FIG. 1(c), a pattern is drawn on the laminated resist (L1+L2) by irradiating the resist with energy rays as shown by an arrow 13 through a mask 11 having a desired pattern and a reduction projection glass 14, thus selectively exposing a specific area 12.

In the present invention, the exposing is carried out in a state of pure water 15 being filled between the reduction projection glass 14 and the laminated resist.

In the first laminated resist of the present invention, intended purposes of obtaining a precise pattern form, high dimensional accuracy of a pattern and reproducibility thereof are accomplished by an effect of the protective layer (L2) in a state of pure water being filled between the glass and the resist.

In this case, for example, g-line (436 nm wavelength), i-line (365 nm wavelength), KrF excimer laser (248 nm wavelength), ArF excimer laser (193 nm wavelength) and the like can be used as the energy rays (or chemical radiation), and resolution can be enhanced in the respective processes.

Particularly in the case of ArF excimer laser (193 nm wavelength), a high resolution effect by immersion exposing is exhibited more.

Subsequently by carrying out post-exposure baking (PEB step) at a temperature of from 70° to 160° C., preferably from 90° to 140° C. for about 30 seconds to about 10 minutes, a latent image is formed on the exposed area 12 of the photoresist layer (L1) as shown in FIG. 1(d). At this time, an acid generated by the exposing acts as a catalyst to decompose the dissolution-inhibiting group (protective group) in the photoresist layer (L1), thereby increasing solubility in a developing solution and making the exposed area of the resist film soluble in a developing solution.

(d) Developing step:

Then when the photoresist layer (L1) after the post-exposure baking is subjected to developing with a developing solution, the un-exposed area of the photoresist layer (L1) remains on the substrate because its solubility in the developing solution is low but the exposed area 12 is dissolved in the developing solution as mentioned above.

On the other hand, the upper protective layer (L2) is excellent in solubility in the developing solution irrespective of the exposed area and un-exposed area, and therefore is removed together with the exposed portion in the developing step.

A 2.38% by weight aqueous solution of tetramethylammonium hydroxide is preferably used as the developing solution. Also to the 2.38% by weight aqueous solution of tetramethylammonium hydroxide may be added a surfactant or alcohol such as methanol, ethanol, propanol or butanol in order to adjust wettability to the surfaces of protective layer (L2) and photoresist layer (L1).

Next, after flowing away the developing solution with pure water, lower alcohol or a mixture thereof, the substrate is dried and thus a desired resist pattern can be formed as shown in FIG. 1(e).

Also when an intended fine pattern of an electrically conductive film or an insulating film is formed by using the so-formed fine resist pattern as a mask and etching a specific layer under the mask and then other steps are carried out, semiconductor devices and electronic devices can be produced. Since those steps are well known, explanation thereof is omitted.

The second laminated resist of the present invention is a laminated resist for immersion lithography using ultraviolet light of not less than 193 nm for exposing and comprises a substrate and a photoresist layer (L3) provided on the substrate. This laminated resist is characterized in that the photoresist layer (L3) is formed on a substrate as an outermost surface of the laminated resist and contains the photoacid generator (B2) and the fluorine-containing polymer (A2) having the protective group Y² which can change to an alkali soluble group by dissociation with an acid.

The present inventors have found that when the laminated resist having the photoresist layer (L3) as an outermost surface is used for immersion photolithography process using pure water as a liquid medium, it is possible to make an improvement in solving a problem with a pattern failure and defect in an immersion exposing process which has been difficult to solve in the case of a film surface of conventional ArF resist or KrF resist.

In the second invention, the photoresist layer (L3) containing the fluorine-containing polymer (A2) is excellent in at least one of water repellency, water resistance and water-proof property, and therefore it can be considered that even if the photoresist layer (L3) is used as an outermost surface and comes into contact with pure water, diffusion and elution of a photoacid generator contained in the photoresist layer (L3) and a quencher can be inhibited.

In the laminated resist of the present invention, the photoresist layer (L3) containing the fluorine-containing polymer (A2) may be applied directly to the substrate or may be applied to a photoresist layer (L3-1) of a conventional ArF resist or KrF resist as a layer having a protective function in the same manner as mentioned above.

Especially it is preferable that water repellency of the photoresist layer (L3) forming an outermost layer is higher to such an extent not to lower developing characteristics significantly after the exposing.

For example, a water contact angle of the photoresist layer (L3) is preferably not less than 70°, more preferably not less than 75°, particularly preferably not less than 80°. An upper limit thereof is preferably not more than 110°, more preferably not more than 100°, particularly preferably not more than 90°.

If the water contact angle of the photoresist layer (L3) surface is too small, after coming into contact with pure water, water permeation becomes fast, thereby increasing water absorption and swelling of the photoresist layer (L3) or causing elution of additives such as a photoacid generator and amines contained in the photoresist layer (L3), which has an adverse effect on resolution and form of a fine pattern. Therefore a too small water contact angle is not preferred. Also a too small water contact angle is not preferred because when the photoresist layer (L3) of the present invention which forms an outermost layer is formed on the conventional photoresist layer (L3-1), water easily reaches the lower photoresist layer (L3-1), which has an adverse effect on resolution and form of a fine pattern like the case mentioned above.

Also a too large water contact angle on the photoresist layer (L3) surface is not preferred because at developing after the exposing, the dissolution rate in a developing solution of the exposed portion is decreased, which has an adverse effect on resolution and form of a fine pattern.

Further the photoresist layer (L3) of the outermost surface having a low water absorbing property (water absorbing rate) is preferred.

If the water absorbing property (water absorbing rate) is too high, after coming into contact with pure water, water permeation becomes fast and a rate of water permeation into the photoresist layer (L3) is increased. Therefore a too high water absorbing property is not preferred.

If the water absorbing property (water absorbing rate) of the photoresist layer (L3) is too high, after coming into contact with pure water, elution of additives such as a photoacid generator and amines contained in the photoresist layer (L3) occurs, which has an adverse effect on resolution and form of a fine pattern. Therefore a too high water absorbing rate is not preferred. Also a too high water absorbing rate is not preferred because when the photoresist layer (L3) of the present invention which forms an outermost layer is formed on the conventional photoresist layer (L3-1), water easily reaches the lower photoresist layer (L3-1), which has an adverse effect on resolution and form of a fine pattern like the case mentioned above.

For example, the water absorbing property (water absorbing rate) can be measured by the QCM method, and calculated as a weight increasing rate by water absorption (water absorbing rate).

In the laminated resist of the present invention, it is necessary that the photoresist layer (L3) forming an outermost layer is transparent to light having a wavelength of not less than 193 nm.

Accordingly an immersion exposing process using pure water can be utilized usefully, for example, even in ArF lithography using 193 nm wavelength and KrF lithography using 248 nm wavelength.

Concretely in the case of a wavelength of not less than 193 nm, an absorption coefficient is not more than 1.0 μm⁻¹, preferably not more than 0.8 μm⁻¹, more preferably not more than 0.5 μm⁻¹, most preferably not more than 0.3 μm⁻¹.

A too large absorption coefficient of the photoresist layer (L3) is not preferred because transparency of the whole laminated resist is lowered, resulting in lowering of resolution at forming a fine pattern and deteriorating a form of a pattern.

It is important that the fluorine-containing polymer (A2) contained in the photoresist layer (L3) of the second laminated resist of the present invention has the protective group Y² which can change to an alkali soluble group by dissociation with an acid. Namely, the fluorine-containing polymer (A2) is one being capable of acting as a positive resist. Accordingly, the photoresist layer (L3) further contains the photoacid generator (B2) as essential component and contains, as case demands, amines and other additives necessary for a resist.

The protective group Y² contained in the fluorine-containing polymer (A2) is a functional group which can make the polymer soluble in alkali by an action of an acid though the polymer is insoluble or less soluble in alkali before reaction with an acid. This change in solubility in alkali makes the fluorine-containing polymer usable as a base polymer for a positive resist.

The protective group Y² has an ability of changing to —OH group, —COOH group, —SO₃H group or the like by an action of an acid or a cation, and as a result, the fluorine-containing polymer itself becomes soluble in alkali.

Examples of the protective group which can be used preferably are:

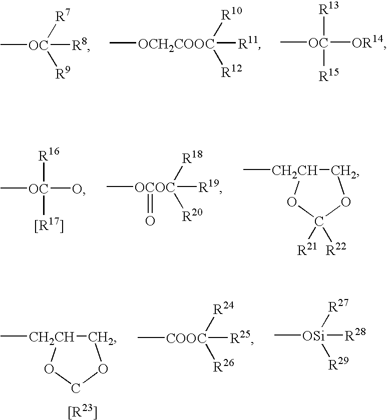

and the like, wherein R⁷, R⁸, R⁹, R¹⁰, R¹¹, R¹², R¹⁴, R¹⁸, R¹⁹, R²⁰, R²¹, R²², R²⁴, R²⁵, R²⁶, R²⁷, R²⁸ and R²⁹ are the same or different and each is a hydrocarbon group having 1 to 10 carbon atoms; R¹³, R¹⁵ and R¹⁶ are the same or different and each is H or a hydrocarbon group having 1 to 10 carbon atoms; and R¹⁷ and R²³ are the same or different and each is a divalent hydrocarbon group having 2 to 10 carbon atoms. More concretely there are preferably:

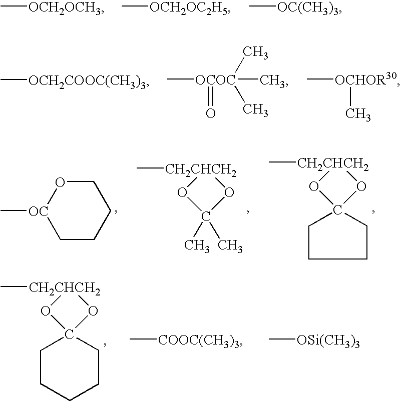

and the like, wherein R³⁰ is an alkyl group having 1 to 10 carbon atoms.

Among the above-mentioned protective groups Y², preferred is at least one of protective groups Y³ which can be converted to OH group by an acid and protective groups Y⁴ which can be converted to COOH group due to dissociation by an acid.

Examples of the protective groups Y³ which can be converted to OH group by an acid are groups represented by:

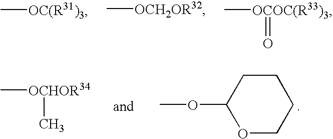

wherein R³¹, R³², R³³ and R³⁴ are the same or different and each is an alkyl group having 1 to 5 carbon atoms.

More concretely there are preferably:

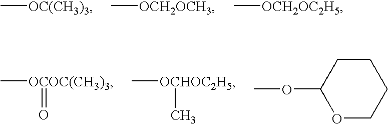

and the like. Particularly preferred are:

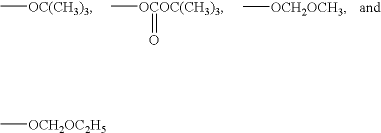

because of good acid reactivity, and —OC(CH₃)₃, —OCH₂OCH₃ and —OCH₂OC2H₅ are preferred because of good transparency.

Examples of the protective groups Y⁴ which can be converted to —COOH group by an acid are:

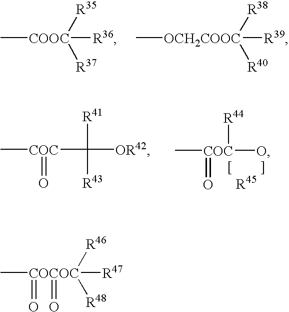

and the like, wherein R³⁵, R³⁶, R³⁷, R³⁸, R³⁹, R⁴⁰, R⁴¹, R⁴², R⁴⁶, R⁴⁷ and R⁴⁸ are the same or different and each is a hydrocarbon group having 1 to 10 carbon atoms; R⁴³ and R⁴⁴ are the same or different and each is H or a hydrocarbon group having 1 to 10 carbon atoms; R⁴⁵ is a divalent hydrocarbon group having 2 to 10 carbon atoms, and particularly preferred are:

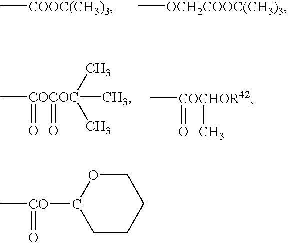

and the like, wherein R⁴² is as defined above.

Among the protective groups Y³ which can be converted to OH group by an acid, preferred are those which can be converted to OH showing acidity of not more than 11 in a pKa value by an acid, further preferably OH group having a pKa value of not more than 10, particularly preferably OH group having a pKa value of not more than 9.

Such a protective group is preferred because developing characteristics after the exposing become good and a fine pattern of high resolution can be obtained.

It is preferable that a fluorine-containing alkyl group or a fluorine-containing alkylene group is bonded to the carbon atom bonded directly to the protective groups Y³ which can be converted to OH group, and preferred is a moiety represented by the following formula:

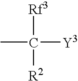

wherein Rf³ is a fluorine-containing alkyl group which has 1 to 10 carbon atoms and may have ether bond; R² is selected from hydrogen atom, hydrocarbon groups having 1 to 10 carbon atoms and fluorine-containing alkyl groups which have 1 to 10 carbon atoms and may have ether bond.

It is preferable that R² is a fluorine-containing alkyl group which has 1 to 10 carbon atoms and may have ether bond.

It is further preferable that both of Rf³ and R² are perfluoroalkyl groups, and concretely preferred are moieties of:

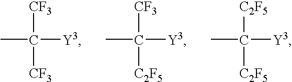

and the like.

Further from the viewpoint of water solubility and solubility in a developing solution, more preferred is a moiety represented by the following formula:

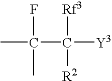

wherein Rf³ is a fluorine-containing alkyl group which has 1 to 10 carbon atoms and may have ether bond; R² is selected from hydrogen atom, hydrocarbon groups having 1 to 10 carbon atoms and fluorine-containing alkyl groups which have 1 to 10 carbon atoms and may have ether bond. Concretely preferred are moieties of:

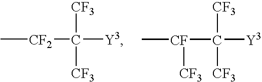

and the like.

It is preferable that the fluorine content of the fluorine-containing polymer (A2) having the protective group Y² is not less than 30% by mass, more preferably not less than 40% by mass, particularly preferably not less than 50% by mass.

A too low fluorine content is not preferred because water repellency is lowered and water absorption is increased too much.

On the other hand, an upper limit of the fluorine content is 75% by mass, preferably 70% by mass, more preferably 65% by mass.

A too high fluorine content is not preferred because water repellency of the coating film becomes too high, thereby decreasing a dissolution rate in a developing solution and deteriorating reproducibility of the dissolution rate in a developing solution.

For the fluorine-containing polymer (A2) having the protective group Y² which is used for the outermost photoresist layer (L3) in the second laminated resist of the present invention, polymers having the same structures as those of the fluorine-containing polymers (A1) having the hydrophilic functional group Y exemplified supra can be used preferably. Namely, the fluorine-containing polymer (A2) is obtained by replacing a part or the whole of the protective groups Y of the fluorine-containing polymer (A1) by at least one kind of the protective groups Y², and as a result, can work as a positive resist.

Concretely preferred examples thereof are polymers obtained by replacing a part or the whole of the OH groups of the fluorine-containing polymers having —OH groups among the fluorine-containing polymers (A1) having the hydrophilic functional group Y by the above-mentioned protective groups Y³ which can be converted to OH groups by an acid.

Also preferred examples thereof are polymers obtained by replacing a part or the whole of the —COOH groups of the fluorine-containing polymers having —COOH groups among the fluorine-containing polymers (A1) having the hydrophilic functional group Y by the above-mentioned protective groups Y⁴ which can be converted to —COOH groups by an acid.

The first of the preferred fluorine-containing polymer (A2) having protective group are fluorine-containing polymers which have the protective group Y² (or Y³ or Y⁴) and a structural unit of an aliphatic ring structure in the trunk chain thereof. Concrete examples thereof are polymers obtained by replacing a part or the whole of the hydrophilic functional groups Y of the polymers of the formulae (M-1) and (M-2) and the concretely exemplified polymers thereof by the protective groups Y² (or Y³ or Y⁴) exemplified above.

Those fluorine-containing polymers (A2) having protective group are preferred from the viewpoint of excellent dry etch resistance and transparency, and further is useful for an immersion lithography process because when used for the outermost photoresist layer (L3), the polymers (A2) can impart at least one of water repellency, water resistance and water-proof property to the laminated resist.

The second of the fluorine-containing polymer (A2) having protective group are polymers having a structural unit derived from a fluorine-containing ethylenic monomer having the protective group Y² (or Y³ or Y⁴).

Concrete examples thereof are polymers obtained by replacing a part or the whole of the hydrophilic functional groups Y of the polymers of the formulae (M-3) and (M-4) and the concretely exemplified polymers thereof by the protective groups Y² (or Y³ or Y⁴) exemplified above.

Those fluorine-containing polymers (A2) having protective group are preferred from the viewpoint of excellent transparency, and further is useful for an immersion lithography process because when used for the outermost photoresist layer (L3), the polymers (A2) can impart at least one of water repellency, water resistance and water-proof property to the laminated resist.

In the second laminated resist of the present invention, the photoresist layer (L3) contains the photoacid generator (B) in addition to the fluorine-containing polymer (A2) having the protective group Y² Preferred examples of the photoacid generator (B) are the same as the examples of the photoacid generator (b) raised in International Publication No. 01/74916. Those photoacid generators can also be used effectively in the present invention.

The photoacid generator is a compound which generates an acid or a cation by irradiation of light. Examples thereof are, for instance, organic halogen compounds, sulfonic acid esters, onium salts (particularly fluoroalkyl onium salts having iodine, sulfur, selenium, tellurium, nitrogen or phosphorus as a center element), diazonium salts, disulfone compounds, sulfonediazides and mixtures thereof.

More preferred examples thereof are as follows.

(1) TPS compound:

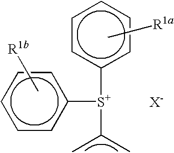

wherein X⁻ is PF6⁻, SbF6⁻, CF₃SO₃⁻, C₄F₉SO₃⁻ or the like; R^{1a}, R^{1b} and R^{1c} are the same or different and each is CH₃O, H, t-Bu, CH₃, OH or the like.

### (2) DPI Compound:

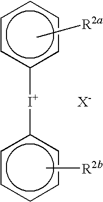

wherein X⁻ is CF₃SO₃⁻, C₄F₉SO₃⁻, CH₃—_{φ}—SO₃⁻, SbF₆⁻,

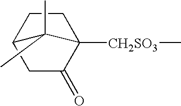

or the like; R^{2a} and R^{2b} are the same or different and each is H, OH, CH₃, CH₃O, t-Bu or the like.

### (3) Sulfonate Compound:

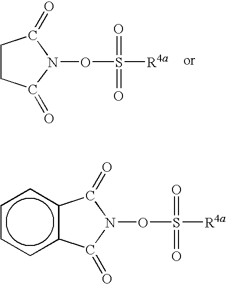

wherein R^{4a} is:

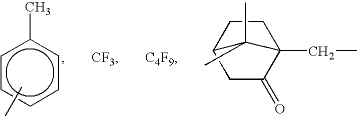

or the like.

Usually the photoresist layer (L3) is formed, for example, by applying the resist composition prepared by dissolving the fluorine-containing polymer (A2) having the protective group Y² and the photoacid generator (B) in the solvent (C2).

The content of photoacid generator (B) used for the resist composition for forming the photoresist layer (L3) in the second laminated resist of the present invention is preferably from 0.1 to 30 parts by weight, more preferably from 0.2 to 20 parts by weight, most preferably from 0.5 to 10 parts by weight based on 100 parts by weight of the fluorine-containing polymer (A2) having the protective group Y².

If the content of photoacid generator (B) is lower than 0.1 part by weight, sensitivity is lowered, and if the content of photoacid generator (B) is more than 30 parts by weight, an amount of light absorbed by the photoacid generator is increased and light does not reach a substrate sufficiently and therefore resolution is easily lowered.

Also to the resist composition for forming the photoresist layer (L3) may be added an organic base being capable of acting as a base on an acid generated from the photoacid generator (B). Examples of preferred organic base are the same as those exemplified in International Publication No. 01/74916. Those organic bases can also be used effectively in the present invention.

The organic base is concretely an organic amine compound selected from nitrogen-containing compounds. Examples thereof are, for instance, pyridine compounds, pyrimidine compounds, amines substituted by a hydroxyalkyl group having 1 to 4 carbon atoms, amino phenols and the like. Particularly preferred are hydroxyl-containing amines.

Examples thereof are butylamine, dibutylamine, tributylamine, triethylamine, tripropylamine, triamylamine, pyridine and the like.

The content of organic base in the resist composition for forming the photoresist layer (L3) is preferably from 0.1 to 100% by mole, more preferably from 1 to 50% by mole based on the content of photoacid generator (B). If the content of organic base is lower than 0.1% by mole, resolution is lowered, and if the content of organic base is more than 100% by mole, sensitivity tends to be lowered.

The resist composition may contain, as case demands, additives disclosed in International Publication No. 01/74916, for example, various additives which have been usually used in this field, such as dissolution inhibitor, sensitizer, dye, adhesion betterment material and water storage material.

Also in the resist composition for forming the photoresist layer (L3) of the second laminated resist of the present invention, examples of the preferred solvent (C2) are the same as those of the solvent (C2) exemplified in International Publication No. 01/74916. Those solvents can also be used effectively in the present invention.

Preferred examples thereof are cellosolve solvents, ester solvents, propylene glycol solvents, ketone solvents, aromatic hydrocarbon solvents and solvent mixtures thereof. Also in order to enhance solubility of the fluorine-containing polymer (A2) having protective group, fluorine-containing solvents such as fluorine-containing hydrocarbon solvents such as CH₃CCl₂F (HCFC-141b) and fluorine-containing alcohols may be used together.

The amount of the solvent (C2) is selected depending on kind of solids to be dissolved, kind of a substrate to be coated, an intended coating thickness, etc. From the viewpoint of easy coating, it is preferable that the solvent is used in such an amount that the concentration of the whole solids of the photoresist composition is from 0.5% to 70% by weight, preferably from 1 to 50% by weight.

In the second laminated resist of the present invention, the first of the preferred laminated resist is a laminated resist (X1) having a layer construction comprising a substrate and the photoresist layer (L3) which contains the fluorine-containing polymer (A2) having protective group and is formed on the substrate.

In the laminated resist (X1), substantially only the photoresist layer (L3) is laminated on the substrate. The photoresist layer (L3) itself has high transparency to ultraviolet light having a wavelength of not less than 193 nm, and acts as a positive resist in a lithography process using such ultraviolet light and makes it possible to form a good pattern. Further the photoresist layer (L3) is preferred since an adverse effect due to water used in an immersion lithography can be reduced to a minimum.

In the laminated resist (X1), a thickness of the photoresist layer (L3) varies depending on kind and purpose of a device to be produced, conditions of processing, e.g. etching for production thereof and kind of the resist layer (degrees of transparency and dry etch resistance), and is optionally selected. The thickness is usually from 10 to 5,000 nm, preferably from 50 to 1,000 nm, more preferably from 100 to 500 nm.

In the second laminated resist of the present invention, the second of the preferred laminated resist is a laminated resist (X2) having a layer construction comprising a substrate, a photoresist layer (L3-1) formed on the substrate previously and the photoresist layer (L3) which contains the fluorine-containing polymer (A2) having protective group and is formed on the photoresist layer (L3-1).

The laminated resist (X2) is produced by laminating the photoresist layer (L3) which contains the fluorine-containing polymer (A2) having protective group and functions as a protective layer against water, on the photoresist layer (L3-1) of a conventional resist material, and both of the photoresist layers (L3-1) and (L3) are subjected to pattern formation at the same time by the exposing and developing steps.

The photoresist layer (L3-1) in the laminated resist is a layer formed by using a conventional photoresist composition, for example, a layer obtained by forming a film by using a positive photoresist containing, as main components, a novolak resin and diazonaphthoquinone (g-line or i-line lithography), a chemically amplifying positive or negative resist prepared using polyhydroxystyrene as a binder resin (KrF lithography), a chemically amplifying positive photoresist prepared using an acrylic polymer having an alicyclic structure in its side chain or an alicyclic polymer having a polynorbornene structure (ArF lithography) or the like.

In the case of using for immersion lithography of the present invention, preferred are a chemically amplifying positive resist prepared using polyhydroxystyrene as a binder resin and a chemically amplifying positive photoresist prepared using an acrylic polymer having an alicyclic structure in its side chain or an alicyclic polymer having a polynorbornene structure, and particularly preferred is a chemically amplifying positive photoresist prepared using an acrylic polymer having an alicyclic structure in its side chain or an alicyclic polymer having a polynorbornene structure.

In the laminated resist (X2), a thickness of the photoresist layer (L3) varies depending on kind of the fluorine-containing polymer (A2) having protective group, immersion exposing conditions, contact time with water and the like, and is optionally selected. The thickness is usually from 1 to 500 nm, preferably from 10 to 300 nm, more preferably from 20 to 200 nm, especially from 30 to 100 nm.

In the laminated resist (X2), a thickness of the photoresist layer (L3-1) varies depending on kind and purpose of a device to be produced, conditions of processing, e.g. etching for production thereof and kind of the resist layer (degrees of transparency and dry etch resistance), and is optionally selected. The thickness is usually from 10 to 5,000 nm, preferably from 50 to 1,000 nm, more preferably from 100 to 500 nm.

This laminated resist (X2) can solve problems attributable to water at immersion exposing while utilizing dry etch resistance and lithographic characteristics (for example, film forming property, sensitivity, resolution and form of a pattern) of the lower photoresist layer (L3-1) though the problems could not be solved sufficiently only by the photoresist layer (L3-1).

Also the laminated resist (X2) is preferred since the outermost photoresist layer (L3) itself containing the fluorine-containing polymer (A2) having protective group can be formed into a pattern having the same form as that of the photoresist layer (L3-1), thereby enabling the form and roughness of the pattern surface after the developing to be enhanced.

Examples of the substrate in the second laminated resists (X1) and (X2) of the present invention are, for instance, a silicon wafer; a glass substrate; a silicon wafer or glass substrate provided with an organic or inorganic antireflection film; a silicon wafer which has steps and is provided with various insulating films, electrode and wiring on the surface thereof; a mask blank; a semiconductor wafer of III-V group compound such as GaAs or AlGaAs and a semiconductor wafer of II-VI group compound; a piezoelectric wafer of crystal, quartz or lithium tantalate and the like.

The formation of the resist is not limited to the case of forming the resist on a so-called substrate. The resist may also be formed on a specific layer such as an electrically conductive film, insulating film or the like which is formed on the substrate. Also it is possible to form an antireflection film (lower antireflection layer), for example, DUV-30, DUV-32, DUV-42 and DUV44 available from Brewer Science Co., Ltd. on the substrate. The substrate may be treated with an adhesion improver.

With respect to the method of forming the photoresist layer (L3) on the substrate, the method of forming the laminated resist by providing the photoresist layer (L3) on the photoresist layer (L3-1) and further the method of forming a fine pattern by immersion exposing by using the laminated resists (X1) and (X2), there can be similarly adopted the mentioned method of forming the laminated resist by providing the protective layer (L2) on the photoresist layer (L1) and further the mentioned method of forming a fine pattern by immersion exposing by using the obtained laminated photoresist.

For example, with respect to the laminated resist (X1), a fine pattern can be formed by employing conventional method of forming a resist layer and carrying out steps including an immersion exposing step.

Also the laminated resist (X2) can be formed by using the photoresist layer (L3-1) instead of the photoresist layer (L1) and using the photoresist layer (L3) instead of the protective layer (L2) in the same manner as mentioned supra, and a fine pattern can be formed by carrying out steps including an immersion exposing step by using the obtained laminated resist in the same manner as mentioned supra.

### EXAMPLES

The present invention is then explained concretely by means of examples, preparation examples and experimental examples but is not limited to them.

### Preparation Example 1

### Synthesis of Copolymer Containing TFE and Fluorine-Containing Norbornene Having OH Group

Into a 500 ml autoclave equipped with a valve, pressure gauge, stirrer and thermometer were poured 35.0 g of fluorine-containing norbornene derivative (NB-1) having OH group:

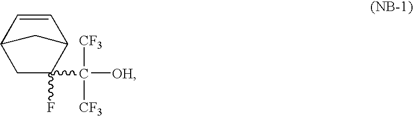

250 ml of HCFC-141b and 6.5 g of bis(4-t-butylcyclohexyl)peroxydicarbonate (TCP), and while cooling with a dry ice/methanol solution, the inside of the system was sufficiently replaced with nitrogen gas. Then 52.0 g of tetrafluoroethylene (TFE) was introduced through the valve, followed by reaction at 40° C. for 12 hours with stirring. With the advance of the reaction, a gauge pressure was decreased from 0.96 MPaG (9.7 kgf/cm²G) before the reaction to 0.91 MPaG (9.2 kgf/cm²G).

After the un-reacted monomer was released, the polymerization solution was taken out, followed by concentration and re-precipitation with hexane to separate a copolymer. Until a constant weight was reached, drying in vacuo was continued and 6.0 g of a copolymer was obtained.

As a result of ¹H-NMR and ¹⁹F-NMR analyses, the copolymer was a copolymer containing TFE and the above-mentioned fluorine-containing norbornene derivative (NB-1) having OH group in a percent by mole ratio of 50/50.

According to GPC analysis, a number average molecular weight of the copolymer was 5,500.

Equipment and measuring conditions used for evaluating physical properties are as follows.

### (1) NMR

NMR measuring equipment: available from BRUKER CO., LTD.
Measuring conditions of ¹H-NMR: 300 MHz (tetramethylsilane=0 ppm)
Measuring conditions of ¹⁹F-NMR: 282 MHz (trichlorofluoromethane=0 ppm)
(2) A number average molecular weight is calculated from the data measured by gel permeation chromatography (GPC) by using GPC HLC-8020 available from Toso Kabushiki Kaisha and columns available from Shodex (one GPC KF-801, one GPC KF-802 and two GPC KF-806M were connected in series) and flowing tetrahydrofuran (THF) as a solvent at a flowing rate of 1 ml/min.

### Preparation Example 2

### Synthesis of Copolymer Containing TFE and Fluorine-Containing Norbornene Having OH Group

Polymerization reaction and separation and refining of a polymer were carried out in the same manner as in Preparation Example 1 except that 32.5 g of norbornene derivative (NB-2) having OH group:

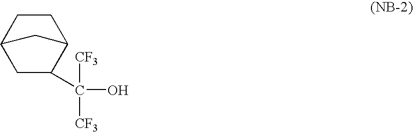

was used instead of the fluorine-containing norbornene derivative (NB-1) having OH group, and 4.5 g of a copolymer was obtained.

As a result of ¹H-NMR and ¹⁹F-NMR analyses, the copolymer was a copolymer containing TFE and the norbornene derivative (NB-2) having —OH group in a percent by mole ratio of 50/50.

According to GPC analysis, a number average molecular weight of the copolymer was 3,800.

### Preparation Example 3

### Synthesis of Copolymer Containing TFE and Fluorine-Containing Norbornene Having OH Group

Reaction and separation and refining of a polymer were carried out in the same manner as in Preparation Example 1 except that 40.0 g of fluorine-containing norbornene derivative (NB-3) having OH group:

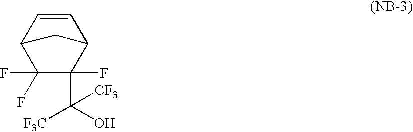

was used instead of the fluorine-containing norbornene derivative (NB-1) having OH group, and 5.5 g of a copolymer was obtained.

As a result of ¹H-NMR and ¹⁹F-NMR analyses, the copolymer was a copolymer containing TFE and the fluorine-containing norbornene derivative (NB-3) having OH group in a percent by mole ratio of 50/50.

According to GPC analysis, a number average molecular weight of the copolymer was 3,500.

### Preparation Example 4

### Synthesis of Copolymer Containing TFE and Fluorine-Containing Norbornene Having —COOC(CH₃)₃ Group

Into a 300 ml autoclave were poured 15.9 g of fluorine-containing norbornene derivative (NBC-1P) having —COOC(CH₃)₃ group:

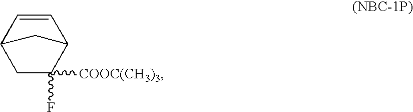

140 ml of HCFC-141b and 1.0 g of bis(4-tert-butylcyclohexyl)peroxydicarbonate (TCP), and while cooling with a dry ice/methanol solution, the inside of the system was sufficiently replaced with nitrogen gas. Then 30.0 g of tetrafluoroethylene (TFE) was introduced through the valve, followed by reaction at 40° C. for 12 hours with shaking. With the advance of the reaction, a gauge pressure was decreased from 1.00 MPaG (10.2 kgf/cm²G) before the reaction to 0.94 MPaG (9.6 kgf/cm²G).

After the un-reacted monomer was released, the polymerization solution was taken out, followed by re-precipitation with methanol to separate a copolymer. Until a constant weight was reached, drying in vacuo was continued and 8.5 g of a copolymer was obtained.

As a result of ¹⁹F-NMR analysis, the copolymer was a copolymer containing TFE and the fluorine-containing norbornene derivative (NBC-1P) having —COOC(CH₃)₃ group in a percent by mole ratio of 50/50.

According to GPC analysis, a number average molecular weight of the copolymer was 4,800.

### Preparation Example 5

### Synthesis of Copolymer Containing Norbornene, TFE and tert-butyl-α-fluoroacrylate

Into a 300 ml autoclave were poured 10.5 g of 2-norbornene, 9.8 g of tert-butyl-α-fluoroacrylate, 140 ml of HCFC-141b and 0.5 g of bis(4-tert-butylcyclohexyl)peroxydicarbonate (TCP), and while cooling with a dry ice/methanol solution, the inside of the system was sufficiently replaced with nitrogen gas. Then 36.0 g of tetrafluoroethylene (TFE) was introduced through the valve, followed by reaction at 40° C. for 12 hours with shaking. With the advance of the reaction, a gauge pressure was decreased from 1.06 MPaG (10.8 kgf/cm²G) before the reaction to 0.88 MPaG (9.0 kgf/cm²G).

After the un-reacted monomer was released, the polymerization solution was taken out, followed by re-precipitation with methanol to separate a copolymer. Until a constant weight was reached, drying in vacuo was continued and 20.9 g of a copolymer was obtained.

As a result of ¹H-NMR and ¹⁹F-NMR analyses, the copolymer was a copolymer containing TFE, 2-norbornene and tert-butyl-α-fluoroacrylate in a percent by mole ratio of 31/30/39.

According to GPC analysis, a number average molecular weight of the copolymer was 9,800.

### Preparation Example 6

### Synthesis of Copolymer Containing TFE, Fluorine-Containing Norbornene Having —COOH Group and Fluorine-Containing Norbornene Having —COOC(CH₃)₃ Group by Deprotection Reaction

In a 100 ml eggplant type flask, 5 g of the fluorine-containing polymer having protective group obtained in Preparation Example 4 was dissolved in 80 g of methylene chloride and 4 g of trifluoroacetic acid was added thereto, followed by stirring at room temperature for 12 hours. After completion of the reaction, excessive trifluoroacetic acid and methylene chloride were distilled off under reduced pressure. The remaining solid component was washed with distilled water, dissolved in tetrahydrofuran, re-precipitated with hexane and dried to separate a copolymer.

As a result of ¹H-NMR and ¹⁹F-NMR analyses, the copolymer was a copolymer containing TFE, fluorine-containing norbornene having —COOH group and fluorine-containing norbornene having —COOC(CH₃)₃ group in a percent by mole ratio of 50/5/45.

### Preparation Example 7

### Synthesis of Copolymer Containing TFE, Fluorine-Containing Norbornene Having —COOH Group and Fluorine-Containing Norbornene Having —COOC(CH₃)₃ Group by Deprotection Reaction

The fluorine-containing polymer having protective group obtained in Preparation Example 4 was subjected to deprotection reaction and separation in the same manner as in Preparation Example 6 except that 16 g of trifluoroacetic acid was used.

As a result of ¹H-NMR and ¹⁹F-NMR analyses, the copolymer was a copolymer containing TFE, fluorine-containing norbornene having —COOH group and fluorine-containing norbornene having —COOC(CH₃)₃ group in a percent by mole ratio of 50/37.5/12.5.

### Preparation Example 8

### Synthesis of Copolymer Containing 2-notbornene, TFE, tert-butyl-α-fluoroacrylate and α-fluoroacrylic Acid by Deprotection Reaction

In a 100 ml eggplant type flask, 5 g of the fluorine-containing polymer having protective group obtained in Preparation Example 5 was dissolved in 80 g of methylene chloride and 4 g of trifluoroacetic acid was added thereto, followed by stirring at room temperature for 12 hours. After completion of the reaction, excessive trifluoroacetic acid and methylene chloride were distilled off under reduced pressure. The remaining solid component was washed with distilled water, dissolved in tetrahydrofuran, re-precipitated with hexane and dried to separate a copolymer.

As a result of ¹H-NMR and ¹⁹F-NMR analyses, the copolymer was a copolymer containing TFE, 2-norbornene, α-fluoroacrylic acid and tert-butyl-α-fluoroacrylate in a percent by mole ratio of 31/30/13/26.

### Preparation Example 9

### Synthesis of Copolymer Containing 2-norbornene, TFE, tert-butyl-α-fluoroacrylate and α-fluoroacrylic Acid by Deprotection Reaction

The fluorine-containing polymer having protective group obtained in Preparation Example 4 was subjected to deprotection reaction and separation in the same manner as in Preparation Example 8 except that 16 g of trifluoroacetic acid was used in Preparation Example 8.

As a result of ¹H-NMR and ¹⁹F-NMR analyses, the copolymer was a copolymer containing TFE, 2-norbornene, α-fluoroacrylic acid and tert-butyl-α-fluoroacrylate in a percent by mole ratio of 31/30/33/6.

### Preparation Example 10

### Synthesis of Copolymer Containing TFE, Fluorine-Containing Norbornene Derivative (NB-1) Having —OH Group and Fluorine-Containing Norbornene Derivative (NB-1P) Having —OCH₂OC2H5 Group

Into a 500 ml autoclave equipped with a valve, pressure gauge, stirrer and thermometer were poured 24.5 g of fluorine-containing norbornene derivative (NB-1) having —OH group, 7.4 g of fluorine-containing norbornene derivative (NB-1P) having —OCH₂OC2H₅ group:

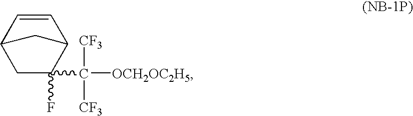

250 ml of HCFC-141b and 6.5 g of bis(4-t-butylcyclohexyl)peroxydicarbonate (TCP), and the inside of the system was sufficiently replaced with nitrogen gas. Then 52.0 g of TFE was introduced through the valve, followed by reaction at 40° C. for 12 hours with stirring.

After the un-reacted monomer was released, the polymerization solution was taken out, followed by concentration and re-precipitation with hexane to separate a copolymer. Until a constant weight was reached, drying in vacuo was continued and 7.2 g of a copolymer was obtained.

As a result of ¹H-NMR and ¹⁹F-NMR analyses, the copolymer was a copolymer containing TFE, the fluorine-containing norbornene derivative (NB-1) having —OH group and the fluorine-containing norbornene derivative (NB-1P) having —OCH₂OC2H₅ group in a percent by mole ratio of 50/40/10.

According to GPC analysis, a number average molecular weight of the copolymer was 3,200.

### Preparation Example 11

### Synthesis Of Fluorine-Containing Polymer Having —COOH as the Hydrophilic Functional Group Y

Into a 100 ml four-necked glass flask equipped with a stirrer and thermometer were poured 21.1 g of perfluoro-(9,9-dihydro-2,5-bistrifluoromethyl-3,6-dioxa-8-nonenoic acid):

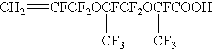

and 21.6 g of 8.0% by weight perfluorohexane solution of:

[H—(CF₂CF₂)₃COO₂

and after sufficiently replacing the inside of the flask with nitrogen gas, polymerization reaction was continued at 20° C. for 24 hours in nitrogen gas atmosphere and a solid having a high viscosity was obtained.

The obtained solid was dissolved in acetone and was poured into n-hexane, followed by separation and drying in vacuo to obtain 17.6 g of a colorless transparent polymer.

According to ¹H-NMR, ¹⁹F-NMR and IR analyses, the obtained polymer was found to be a fluorine-containing polymer containing only a structural unit of the above-mentioned fluorine-containing allyl ether having COOH group.

According to GPC analysis, a number average molecular weight of the copolymer was 22,000.

### Preparation Example 12

### Synthesis of Fluorine-Containing Polymer Having OH Group as the Hydrophilic Functional Group Y)

Polymerization reaction and separation of a polymer were carried out in the same manner as in Preparation Example 11 except that 20.4 g of (1,1,9,9-tetrahydro-2,5-bistrifluoromethyl-3,6-dioxa-8-nonenol):

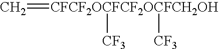

was used instead of perfluoro-(9,9-dihydro-2,5-bistrifluoromethyl-3,6-dioxa-8-nonenoic acid), and 17.1 g of a colorless transparent polymer was obtained.

According to ¹H-NMR and ¹⁹F-NMR analyses, the obtained polymer was found to be a fluorine-containing polymer containing only a structural unit of the above-mentioned fluorine-containing allyl ether having OH group.

### Preparation Example 13

### Synthesis of Fluorine-Containing Polymer Having Cooh Group as the Hydrophilic Functional Group Y

Into a 100 ml four-necked glass flask equipped with a stirrer and thermometer were poured 5.0 g of 1,1,2,4,4,8-hexahydro-3-oxa-1-octene:

CH₂═CHOCH₂(CF₂CF₂)₂—H,

50 g of ethyl acetate and 0.03 g of azobisisobutyronitrile (AIBN), and after replacing the inside of the system with nitrogen gas, 5 g of 2-(trifluoromethyl)acrylic acid:

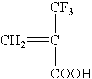

was added in a stream of nitrogen gas and a reaction was continued at 60° C. with stirring.

The obtained reaction solution was taken out and was subjected to re-precipitation with a hexane solvent to separate a solid. This solid was dried in vacuo until a constant weight was reached, and 9.1 g of a copolymer in the form of white powder was obtained.

According to ¹H-NMR and ¹⁹F-NMR analyses, the copolymer was one containing perfluoro(1,1,2,4,4,8-hexahydro-3-oxa-1-octene) and 2-(trifluoromethyl)acrylic acid in a percent by mole ratio of 50/50.

According to GPC analysis, a number average molecular weight thereof was 87,000.

### Preparation Example 14

### Synthesis of Fluorine-Containing Polymer Having OH Group as the Hydrophilic Functional Group Y

Into a 100 ml stainless steel autoclave equipped with a valve, pressure gauge and thermometer were poured 5.2 g of 1,1-bistrifluoromethyl-3-buten-1-ol:

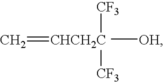

30 ml of CH₃CCl₂F (HCFC-141b) and 10 g of 10% by mole perfluorohexane solution of n-heptafluorobutyryl peroxide (HBP), and the inside of the system was sufficiently replaced with nitrogen gas while cooling with dry ice/methanol solution. Then 10 g of tetrafluoroethylene (TFE) was introduced through the valve and a reaction was carried out at 30° C. with shaking. During the reaction, there was no change in a gauge pressure in the system (9.0 MPaG before starting of the reaction), and also 20 hours after, the gauge pressure was 9.0 MPaG.

Twenty hours after starting of the reaction, the unreacted monomer was released. The precipitated solid was taken out and dissolved in acetone and was subjected to re-precipitation with a hexane solvent to separate and refine the solid. The solid was dried in vacuo until a constant weight was reached, and 3.0 g of a copolymer was obtained.

According to ¹H-NMR and ¹⁹F-NMR analyses, the copolymer was one containing 1,1-bistrifluoromethyl-3-buten-1-ol and tetrafluoroethylene in a percent by mole ratio of 50/50.

According to GPC analysis, a number average molecular weight thereof was 4,900.

### Preparation Example 15

### Synthesis of Fluorine-Containing Polymer Having Protective Group Y²

Into a 1-liter four-necked flask equipped with a stirrer, thermometer and dropping funnel was poured 60 g of the fluorine-containing norbornene derivative (NB-1) having OH group prepared in the same manner as in Preparation Example 1, and after replacing the inside of the reaction system with N₂, 120 ml of N,N-dimethylformamide (DMF) was added to completely dissolve the polymer.

Then 55.5 g (318 mmol) of chloromethyl-2-methylnorbornyl ether:

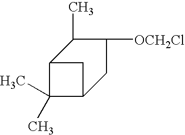

was added thereto, and 120 ml (862 mmol) of triethylamine was added dropwise so that the inside temperature became 20° C. or lower. After completion of the addition, stirring was carried out at room temperature for three hours.

After completion of the reaction, 600 ml of pure water was added to the reaction mixture with stirring and a solid was precipitated, followed by allowing to stand. Then the upper solution layer was removed by decantation, and further 600 ml of pure water was added. Then the same procedures were repeated once and a precipitated solid was separated by filtration.

This solid was dissolved in 300 ml of ethyl acetate and washed with 150 ml of pure water once. Then 10 ml of acetic acid was added to the ethyl acetate layer, followed by washing with 150 ml of pure water until a pH value became 5 or more.

To the washed ethyl acetate layer was added 50 ml of dioxane and the solvent was distilled off under reduced pressure on a hot bath to obtain a solid. This solid was dissolved in HCFC-141b, followed by re-precipitation in 1.5 liter of n-hexane. The precipitated solid was separated by filtration and dried in vacuo to obtain 34.4 g of a fluorine-containing polymer having protective group Y².

According to ¹H-NMR and ¹⁹F-NMR analyses, the fluorine-containing polymer having protective group was a fluorine-containing polymer having a structural unit (NB-1P-1) which is derived from a norbornene derivative having protective group and represented by the formula (NB-1P-1):

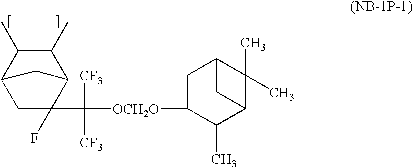

and according to ¹⁹F-NMR analysis, the polymer was one containing TFE, the norbornene derivative (NB-1) having OH group and the norbornene derivative (NB-1P-1) having protective group in a percent by mole ratio of 50/31.5/18.5.

According to GPC analysis, a weight average molecular weight thereof was 3,200.

### Experimental Example 1

### To Confirm Solubility of Fluorine-Containing Polymer in a Solvent

Solubility in various solvents shown in Table 1 was confirmed using the fluorine-containing polymers having hydrophilic functional group which were obtained in Preparation Examples 1 to 14.

The polymers were blended in each solvent shown in Table 1 so that concentrations thereof became 5% by mass, and were allowed to stand at room temperature for 24 hours with stirring. Then appearance of the solution was evaluated. The evaluation was made by the following criteria. The results are shown in Table 1.

◯: A polymer is completely soluble, and a solution becomes transparent and homogeneous.
X: A polymer is partly insoluble or completely insoluble, and a solution is not transparent.

TABLE 1

| | Water | Methanol | Ethanol | PGMEA |
|---|---|---|---|---|
| Preparation Example 1 | X | ◯ | ◯ | ◯ |
| Preparation Example 2 | X | ◯ | ◯ | ◯ |
| Preparation Example 3 | X | ◯ | ◯ | ◯ |
| Preparation Example 4 | X | X | X | ◯ |
| Preparation Example 5 | X | X | X | ◯ |
| Preparation Example 6 | X | X | X | ◯ |
| Preparation Example 7 | X | ◯ | ◯ | ◯ |
| Preparation Example 8 | X | X | X | ◯ |
| Preparation Example 9 | X | ◯ | ◯ | ◯ |
| Preparation Example 10 | X | X | X | ◯ |
| Preparation Example 11 | ◯ | ◯ | ◯ | ◯ |
| Preparation Example 12 | X | ◯ | ◯ | ◯ |
| Preparation Example 13 | ◯ | ◯ | ◯ | ◯ |
| Preparation Example 14 | X | ◯ | ◯ | ◯ |
| Preparation Example 15 | X | X | X | ◯ |

PGMEA: Propylene glycol monomethyl ether acetate

### Experimental Example 2

### Measurement of a pKa Value of a Monomer Having Hydrophilic Functional Group Y

With respect to the monomers having hydrophilic functional group used in Preparation Examples 1 to 3, 7, 9 and 11 to 14, a pKa value of the hydrophilic group thereof was measured and calculated by the following method.

### (Method of Measuring and Calculating a Pka Value)

The method of measuring and calculating a pKa value is mentioned below using 1,1-bistrifluoromethyl-3-buten-1-ol:

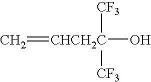

(used in Preparation Example 14) as an example of a monomer.

In a water/acetone solution of 10/15 ml was poured 0.7865 g of CH₂═CHCH₂C(CF₃)₂OH, followed by stirring at room temperature. After it was confirmed that the solution was homogeneous, titration was carried out with 0.2 mole/L NaOH solution. A titration curve was obtained by adding the NaOH solution dropwise in increments of 0.15 ml and recording a pH value at every addition. An equivalence point was determined by an inflection point (maximum differential value of titration curve=dpH/dml) of the titration curve. In this case, the equivalence point was 14.5 ml. A pH value at 7.25 ml which was a half of the equivalence point was read from the titration curve and was found to be 10.58. From a titration curve of water/acetone solution and aqueous solution which had been measured previously as a blank solution, a difference in a pH value derived from an electric potential difference between the solutions at titration of 7.25 ml was 1.29. Therefore from 10.98−1.29=9.69, it was decided that a pKa value of this CH₂═CHCH₂C(CF₃)₂OH was 9.69.

In the case of titration of 1.0865 g of CH₂═CHCH₂C(CF₃)₂OH by the same procedures as above, an equivalence point was 20.15 ml and a half of the equivalence point was 10.08 ml. A pH value at a half of the equivalence point was 10.78. A difference in a pH value between the both solutions at 10.08 ml was 1.14, and from 10.78−1.14=9.64, it was decided that a pKa value of CH₂═CHCH₂C(CF₃)₂OH was 9.64.

When the same procedures as above were carried out by changing the titration solution to about 0.05 mole/L NaOH, an equivalence point of 0.115 g of CH₂═CHCH₂C(CF₃)₂OH was 8.00 ml and a half of the equivalence point was 4.00 ml. A pH value at this time was 10.92. A difference in a pH value between the both solutions at 4.00 ml was 1.38, and from 10.92−1.38=9.54, it was decided that a pKa value of CH₂═CHCH₂C(CF₃)₂OH was 9.54.

From those experiments carried out three times, it was decided that the pKa value of CH₂═CHCH₂C(CF₃)₂OH was 9.6.

With respect to the various fluorine-containing ethylenic monomers having OH group shown in Table 2, a pKa value was measured by the same procedures as above. The results are shown in Table 2.

TABLE 2

| | Monomer having hydrophilic functional group Y | pKa |
|---|---|---|
| Prep. Ex. 1 | 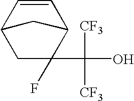 | 9.0 |
| Prep. Ex. 2 | 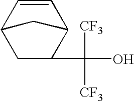 | 10.2 |
| Prep. Ex. 3 | 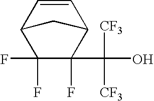 | 8.3 |
| Prep. Ex. 7 | 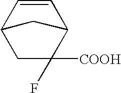 | 3.8 |
| Prep. | CH₂═CF—COOH | 3.4 |
| Ex. 9 | | |
| Prep. Ex. 11 | 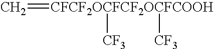 | 3.6 |
| Prep. Ex. 12 | 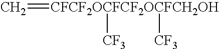 | 12.6 |
| Prep. Ex. 13 | 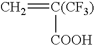 | 3.9 |
| Prep. Ex. 14 | 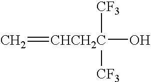 | 9.6 |

### Experimental Example 3

### Preparation of Coating Composition

(1) The fluorine-containing polymers having hydrophilic functional group Y obtained in Preparation Examples 1 to 3, 7, 9 and 11 to 14 were dissolved in methanol at a concentration of 5% by weight, followed by filtration through a 0.2 μm filter, and homogeneous coating compositions were obtained.
(2) The fluorine-containing polymers having protective group Y² obtained in Preparation Examples 4 to 6, 8, 10 and 15 were dissolved in PGMEA at a concentration of 5% by weight, followed by filtration through a 0.2 μm filter, and homogeneous coating compositions were obtained.

### Experimental Example 4

### Measurement of Transparency at 193 nm

### (1) Coating

Each coating composition obtained in Experimental Example 3 was applied on a MgF₂ substrate with a spin coater so that the coating thickness after the drying would become 100 nm. After the coating, baking was carried out at 100° C. for five minutes to form transparent coating films.

### (2) Measurement of Transparency in a Vacuum Ultraviolet Region

### (2-1) Measuring Device

Setani-Namioka type spectrometer (BL-7B available from HIGH ENERGY KENKYU KIKO)

Slit: 7/8-7/8

Detector: PMT

Grating (GII: Blaze wavelength 160 nm, 1,200 gratings/mm)

For an optical system, refer to Rev. Sic. Instrum., 60(7), 1917 (1989) by H. Namba, et al.

### (2-2) Measurement of Transmitting Spectrum

A transmitting spectrum of the coating film formed by applying each coating composition on the MgF₂ substrate by the method of (1) was measured using the above-mentioned device. A molecular absorption coefficient was calculated from the transmittance at 193 nm and the coating thickness. The results are shown in Table 3.

### Experimental Example 5

### Measurement of Solubility in a Developing Solution

A dissolution rate (nm/sec) in a developing solution was measured by the quartz crystal oscillation method (QCM method) mentioned below. The results are shown in Table 3.

(1) Production of sample:

The respective coating compositions prepared in Experimental Example 3 were applied on a 24 mm diameter quartz oscillation panel coated with gold and were dried to make about 100 nm thick coating films.

### (2) Measurement of Dissolution Rate in a Developing Solution:

A coating film thickness is calculated by converting the number of oscillations of the quartz crystal oscillation panel.

The quartz oscillation panel produced above by coating the fluorine-containing polymer was dipped in a 2.38% by weight aqueous solution of tetramethylammonium hydroxide (TMAH) as a standard developing solution. After the dipping of the panel, a change in a coating thickness was obtained from a change in the number of oscillations with the progress of time, and a dissolution rate per unit time (nm/sec) was calculated (Reference bulletin: Advances in Resist Technology and Proceedings of SPIE Vol. 4690, 904 (2002)).

TABLE 3

| | Absorption coefficient | Dissolution rate |
|---|---|---|
| | at 193 nm | in a developing |
| | (μm⁻¹) | solution (nm/sec) |
| Prep. Ex. 1 | 0.30 | 190 |
| Prep. Ex. 2 | 0.32 | 65 |
| Prep. Ex. 3 | 0.33 | 70 |
| Prep. Ex. 4 | 0.55 | insoluble |
| Prep. Ex. 5 | 0.38 | insoluble |
| Prep. Ex. 6 | 0.52 | insoluble |
| Prep. Ex. 7 | 0.48 | 600 |
| Prep. Ex. 8 | 0.35 | insoluble |
| Prep. Ex. 9 | 0.33 | 400 |
| Prep. Ex. 10 | 0.31 | insoluble |
| Prep. Ex. 11 | 0.20 | 150 |
| Prep. Ex. 12 | 0.21 | insoluble |
| Prep. Ex. 13 | 0.30 | 1000 |
| Prep. Ex. 14 | 0.25 | 300 |
| Prep. Ex. 15 | 0.32 | insoluble |

### Example 1

### Formation of Laminated Resist

(1) Formation of photoresist layer (L1)

A photoresist TArF-P6071 for ArF lithography (available from Tokyo Ohka Kogyo Kabushiki Kaisha) was coated on a 8-inch silicon substrate with a spin coater while changing the number of revolutions to adjust the coating thickness to be 200 to 300 nm, followed by pre-baking at 130° C. for 60 seconds to form the photoresist layer (L1).

### (2) Formation of Protective Layer (L2)

On the photoresist layer (L1) formed in above (1) were coated the respective coating compositions containing the fluorine-containing polymers having hydrophilic group (Preparation Examples 1 to 3, 7, 9 and 11 to 14) which were prepared in (1) of Experimental Example 3 with a spin coater firstly at 300 rpm for three seconds and then at 4,000 rpm for twenty seconds while rotating the wafer and adjusting the coating thickness to be about 100 nm to form the protective layer (L2). Thus the laminated photoresist was formed.

### (3) Measurement of Water Contact Angle

Among the laminated resists obtained in (2) above, with respect to the laminated resists produced using the coating compositions prepared from the polymers of Preparation Examples 1 to 3, a contact angle of pure water on a surface thereof was measured at room temperature with a contact angle meter. The results are shown in Table 4.

### (4) Confirmation of Solubility in a Developing Solution

Further with respect to all the laminated resists obtained in (2) above, stationary puddle-developing was carried out at 23° C. for 60 seconds by using a 2.38% by weight developing solution of tetramethylammonium hydroxide and then rinsing with pure water was carried out.

As a result, it was confirmed that in any of the coating compositions, the protective layer (L2) had been selectively removed.

### Example 2

### Production of Laminated Resist

### (1) Preparation of Resist Composition

With respect to the fluorine-containing polymers (A2) having protective group obtained in Preparation Examples 6, 8, 10 and 15, to 100 parts by weight of the fluorine-containing copolymer was added 2 parts by weight of triphenylsulfonium-trifluoromethyl sulfonate as a photoacid generator. Then the mixture was dissolved in 2-heptanone (MAK) to obtain a resist composition having a polymer concentration of 10% by weight.

### (2) Formation of Photoresist Layer (L3-1)

A photoresist TArF-P6071 for ArF lithography (available from Tokyo Ohka Kogyo Kabushiki Kaisha) was coated on a 8-inch silicon substrate with a spin coater while changing the number of revolutions to adjust the coating thickness to be 200 to 300 nm, followed by pre-baking at 130° C. for 60 seconds to form the photoresist layer (L3-1).

### (3) Formation of Photoresist Layer (L3)

On the photoresist layer (L3-1) formed in above (2) were coated the respective resist compositions containing the fluorine-containing polymers having protective group (Preparation Examples 6, 8, 10 and 15) which were prepared in above (1) with a spin coater firstly at 300 rpm for three seconds and then at 4,000 rpm for twenty seconds while rotating the wafer and adjusting the coating thickness to be about 100 nm to form the photoresist layer (L3). Thus the laminated photoresist was formed.

### (4) Measurement of Water Contact Angle

Among the laminated resists obtained in (3) above, with respect to the laminated resist produced using the coating composition containing the polymer of Preparation Example 10, a contact angle of pure water on a surface thereof was measured at room temperature with a contact angle meter. The results are shown in Table 4.

TABLE 4

| | Fluorine-containing polymer | Water contact angle |
|---|---|---|
| | of outermost layer | (degree) |
| Ex. 1 | Prep. Ex. 1 | 77 |
| | Prep. Ex. 2 | 73 |
| | Prep. Ex. 3 | 92 |
| Ex. 2 | Prep. Ex. 10 | 80 |
| | Prep. Ex. 15 | 77 |

### Experimental Example 6

### Measurement of Dissolution Rate in Pure Water

With respect to the fluorine-containing polymers synthesized in Preparation Examples 1 to 3, 10 and 15, a dissolution rate (nm/sec) in pure water was measured by the quartz crystal oscillation method (QCM method) mentioned below. The results are shown in Table 5.

### (1) Production of Sample

The respective coating compositions prepared in Experimental Example 3 (compositions prepared using the fluorine-containing polymers of Preparation Examples 1 to 3, 10 and 15) were applied on a 24 mm diameter quartz oscillation panel coated with gold and were dried to make about 100 nm thick coating films.

### (2) Measurement of Dissolution Rate in Pure Water

A coating film thickness is calculated by converting the number of oscillations of the quartz crystal oscillation panel. The quartz oscillation panel produced above by coating the fluorine-containing polymer was dipped in pure water for about five minutes. After the dipping of the panel, a change in a coating thickness was obtained from a change in the number of oscillations with the progress of time, and a dissolution rate per unit time (nm/min) was calculated.

TABLE 5

| | Dissolution rate in pure water |
|---|---|
| Fluorine-containing polymer | (nm/min) |
| Preparation Example 1 | 1.28 |
| Preparation Example 2 | 1.10 |
| Preparation Example 3 | 1.0 or less |
| Preparation Example 10 | 1.0 or less |
| Preparation Example 15 | 1.0 or less |

### Preparation Example 16

### Synthesis of Fluorine-Containing Polymer Having COOH Group and OH Group as the Hydrophilic Functional Group Y

Polymerization reaction and separation of a polymer were carried out in the same manner as in Preparation Example 11 except that 19.0 g of perfluoro-(9,9-dihydro-2,5-bistrifluoromethyl-3,6-dioxa-8-nonenoic acid) and 1.3 g of perfluoro-(1,1,6,6-tetrahydro-2-trifluoromethyl-3-oxa-5-hexenol):

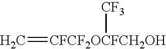

were used instead of 21.1 g of perfluoro-(9,9-dihydro-2,5-bistrifluoromethyl-3,6-dioxa-8-nonenoic acid), and 16.1 g of a colorless transparent polymer was obtained.

According to ¹H-NMR and ¹⁹F-NMR analyses, the obtained copolymer was found to be a fluorine-containing polymer containing the above-mentioned fluorine-containing allyl ether having COOH group and the above-mentioned fluorine-containing allyl ether having OH group in a percent by mole ratio of 90/10.

According to GPC analysis, a number average molecular weight of the polymer was 20,000.

### Preparation Example 17

### Synthesis of Fluorine-Containing Polymer Having COOH Group and OH Group as the Hydrophilic Functional Group Y

Polymerization reaction and separation of a polymer were carried out in the same manner as in Preparation Example 11 except that 9.0 g of perfluoro-(6,6-dihydro-2-trifluoromethyl-3-oxa-5-hexenoic acid):

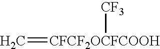

and 6.2 g of perfluoro-(1,1,9,9-tetrahydro-2,5-bistrifluoromethyl-3,6-dioxa-8-nonenol) used in Preparation Example 12 were used instead of perfluoro-(9,9-dihydro-2,5-bistrifluoromethyl-3,6-dioxa-8-nonenoic acid), and 12.1 g of a colorless transparent polymer was obtained.

According to ¹H-NMR and ¹⁹F-NMR analyses, the obtained copolymer was found to be a fluorine-containing polymer containing the above-mentioned fluorine-containing allyl ether having COOH group and the above-mentioned fluorine-containing allyl ether having OH group in a percent by mole ratio of 70/30.

According to GPC analysis, a number average molecular weight of the polymer was 21,000.

### Preparation Example 18

### Synthesis of Fluorine-Containing Polymer Having COOH Group and OH Group as the Hydrophilic Functional Group Y

Polymerization reaction and separation of a polymer were carried out in the same manner as in Preparation Example 11 except that 6.4 g of perfluoro-(6,6-dihydro-2-trifluoromethyl-3-oxa-5-hexenoic acid) used in Preparation Example 17 and 6.1 g of perfluoro-(1,1,6,6-tetrahydro-2-trifluoromethyl-3-oxa-5-hexenol) used in Preparation Example 16 were used instead of perfluoro-(9,9-dihydro-2,5-bistrifluoromethyl-3,6-dioxa-8-nonenoic acid), and 10.5 g of a colorless transparent polymer was obtained.

According to ¹H-NMR and ¹⁹F-NMR analyses, the obtained copolymer was found to be a fluorine-containing polymer containing the above-mentioned fluorine-containing allyl ether having COOH group and the above-mentioned fluorine-containing allyl ether having OH group in a percent by mole ratio of 50/30.

According to GPC analysis, a number average molecular weight of the polymer was 22,000.

### Experimental Example 7

### Preparation of Coating Composition

The fluorine-containing polymers having hydrophilic functional group Y obtained in Preparation Examples 16 to 18 were dissolved in methyl amyl ketone (MAK) at a concentration of 5% by weight, followed by filtration through a 0.2 μm filter, and homogeneous coating compositions were obtained.

### Experimental Example 8

### Measurement of Transparency at 193 nm

Transparency at 193 nm of each coating composition obtained in Experimental Example 7 was measured in the same manner as in Experimental Example 4. The results are shown in Table 6.

### Experimental Example 9

### Measurement of Solubility in a Developing Solution

A dissolution rate (nm/sec) in a developing solution was measured by the quartz crystal oscillation method (QCM method) in the same manner as in Experimental Example 5 except that the coating compositions obtained in Experimental Example 7 were used. The results are shown in Table 6.

### Experimental Example 10

### Measurement of Dissolution Rate in Pure Water

A dissolution rate (nm/min) in pure water was measured by the quartz crystal oscillation method (QCM method) in the same manner as in Experimental Example 6 except that the coating compositions obtained in Experimental Example 7 were used.

TABLE 6

| | Transparency | Solubility in a | Solubility in pure |
|---|---|---|---|
| | at 193 nm | developing solution | water |
| | (μm⁻¹) | (nm/sec) | (nm/min) |
| Prep. | 0.2 | 60 | 1.0 or less |
| Ex. 16 | | | |
| Prep. | 0.2 | 70 | 3.1 |
| Ex. 17 | | | |
| Prep. | 0.2 | 1000 | 8.5 |
| Ex. 18 | | | |

### Example 3

### Formation of Laminated Resist

Laminated resists were formed in the same manner as in Example 1 except that each coating composition prepared in Experimental Example 7 was used for the protective layer (L2), and a water contact angle thereof was measured. The results are shown in Table 7.

TABLE 7

| Fluorine-containing polymer of | |
|---|---|
| outermost layer | Water contact angle (degrees) |
| Preparation Example 16 | 72 |
| Preparation Example 17 | 76 |
| Preparation Example 18 | 59 |

### Preparation Example 19

### Synthesis of Copolymer Containing TFE, Undecylenic Acid and Cyclohexyl Vinyl Ether

A 500 ml autoclave equipped with a valve, pressure gauge, stirrer and thermometer was subjected to replacement with nitrogen and evacuation in this order several times to evacuate the inside of the autoclave (inside of the system). Into the system were poured 62.5 g of undecylenic acid: CH₂═CH(CH₂)₈COOH, 2.4 g of cyclohexyl vinyl ether: CH₂═CHOC₆H₁₁ and 250 g of acetone solution. Then 35.0 g of tetrafluoroethylene (TFE) was introduced to the autoclave through the valve. After heating up the inside of the system to 60° C. with stirring, 1.9 g of pressurized t-butyl peroxypivalate (PERBUTYL PV available from NOF CORPORATION) was introduced to the inside of the system, followed by reaction at 60° C. for six hours with stirring.

After the unreacted monomer was released, the polymerization solution was taken out, and after concentration, was re-precipitated with hexane twice to separate a copolymer. Until a constant weight was reached, drying in vacuo was carried out to obtain 46.0 g of a copolymer.

According to ¹H-NMR and ¹⁹F-NMR analyses, the obtained copolymer was found to be a copolymer containing TFE, undecylenic acid and cyclohexyl vinyl ether in a percent by mole ratio of 50/47/3.

According to GPC analysis, a number average molecular weight of the polymer was 4,800.

### Preparation Example 20

### Synthesis of Copolymer Containing TFE, Undecylenic Acid and Hydroxybutyl Vinyl Ether

A 500 ml autoclave equipped with a valve, pressure gauge, stirrer and thermometer was subjected to replacement with nitrogen and evacuation in this order several times to evacuate the inside of the autoclave (inside of the system). Into the system were poured 62.5 g of undecylenic acid: CH₂═CH(CH₂)₈COOH, 2.1 g of hydroxybutyl vinyl ether: CH₂═CHO(CH₂)₄OH and 250 g of acetone solution. Then 35.0 g of tetrafluoroethylene (TFE) was introduced to the autoclave through the valve. After heating up the inside of the system to 60° C. with stirring, 1.9 g of pressurized t-butyl peroxypivalate (PERBUTYL PV available from NOF CORPORATION) was introduced to the inside of the system, followed by reaction at 60° C. for six hours with stirring.

After the unreacted monomer was released, the polymerization solution was taken out, and after concentration, was re-precipitated with hexane twice to separate a copolymer. Until a constant weight was reached, drying in vacuo was carried out to obtain 44.0 g of a copolymer.

According to ¹H-NMR and ¹⁹F-NMR analyses, the obtained copolymer was found to be a copolymer containing TFE, undecylenic acid and hydroxybutyl vinyl ether in a percent by mole ratio of 50/46/4.

According to GPC analysis, a number average molecular weight of the copolymer was 5,500.

### Preparation Example 21

### Synthesis of Copolymer Containing TFE, Undecylenic Acid and Perfluoropropyl Vinyl Ether

A 500 ml autoclave equipped with a valve, pressure gauge, stirrer and thermometer was subjected to replacement with nitrogen and evacuation in this order several times to evacuate the inside of the autoclave (inside of the system). Into the system were poured 62.5 g of undecylenic acid: CH₂═CH(CH₂)₈COOH, 2.1 g of perfluoropropyl vinyl ether: CF₂═CFOCF₂CF₂CF₃ and 250 g of acetone solution. Then 35.0 g of tetrafluoroethylene (TFE) was introduced to the autoclave through the valve. After heating up the inside of the system to 60° C. with stirring, 1.9 g of pressurized t-butyl peroxypivalate (PERBUTYL PV available from NOF CORPORATION) was introduced to the inside of the system, followed by reaction at 60° C. for six hours with stirring.

After the unreacted monomer was released, the polymerization solution was taken out, and after concentration, was re-precipitated with hexane twice to separate a copolymer. Until a constant weight was reached, drying in vacuo was carried out to obtain 44.0 g of a copolymer.

According to ¹H-NMR and ¹⁹F-NMR analyses, the obtained copolymer was found to be a copolymer containing TFE, undecylenic acid and perfluoropropyl vinyl ether in a percent by mole ratio of 50/46/4.

According to GPC analysis, a number average molecular weight of the copolymer was 4,900.

### Preparation Example 22

### Synthesis of Fluorine-Containing Polymer Having —OH as the Hydrophilic Functional Group Y

Into a 1-liter three-necked flask equipped with a thermometer, cooling tube and dropping funnel was poured 314 g of ethyl perfluoro-(6,6-dihydro-2-trifluoromethyl-3-oxa-5-hexenoate):

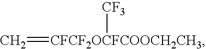

followed by cooling on an ice bath in nitrogen gas atmosphere. Thereto was added dropwise 143 g of CF₃Si(CH₃)₃ over two hours while maintaining the inside temperature of the flask at 50 to 15° C. After increasing to room temperature, the solution was stirred overnight. The reaction solution was poured into an ice bath, followed by extraction with diethyl ether. The organic layer was washed with hydrochloric acid and saturated brine and dried with magnesium sulfate. The magnesium sulfate was filtrated, and the filtrate was concentrated and poured again into the 1-liter three-necked flask equipped with a thermometer, cooling tube and dropping funnel, followed by cooling on an ice bath in nitrogen gas atmosphere. Thereto was added dropwise 143 g of CF₃Si(CH₃)₃ over two hours while maintaining the inside temperature of the flask at 5° to 15° C. After increasing to room temperature, stirring was continued overnight. The reaction solution was then poured into an ice bath, followed by extraction with diethyl ether. The organic layer was washed with hydrochloric acid and saturated brine and dried with magnesium sulfate. The magnesium sulfate was filtrated, followed by refining by distillation, and 240 g of perfluoro-(6,6-dihydro-1,1,2-tristrifluoromethyl-3-oxa-5-hexanol):

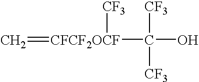

was obtained.

Next, polymerization reaction and separation of a polymer were carried out in the same manner as in Preparation Example 11 except that 18.1 g of perfluoro-(6,6-dihydro-1,1,2-tristrifluoromethyl-3-oxa-5-hexanol) was used instead of perfluoro-(9,9-dihydro-2,5-bistrifluoromethyl-3,6-dioxa-8-nonenoic acid) and 14.1 g of a colorless transparent polymer was obtained.

According to ¹H-NMR, ¹⁹F-NMR and IR analyses, the obtained polymer was found to be a fluorine-containing polymer containing only a structural unit of the above-mentioned fluorine-containing allyl ether having OH group.

According to GPC analysis, a number average molecular weight of the polymer was 20,000.

### Preparation Example 23

### Synthesis of Fluorine-Containing Polymer Having —OH as the Hydrophilic Functional Group Y

Into a 1-liter three-necked flask equipped with a thermometer, cooling tube and dropping funnel was poured 102 g of α-fluoroacrylic acid fluoride, followed by cooling on an ice bath in nitrogen gas atmosphere. Thereto was added dropwise 386 g of CF₃Si(CH₃)₃ over two hours while maintaining the inside temperature of the flask at 5° to 15° C. After increasing to room temperature, stirring was continued overnight. The reaction solution was poured into an ice bath, followed by extraction with diethyl ether.

The organic layer was washed with hydrochloric acid and saturated brine and dried with magnesium sulfate, followed by refining by distillation, and 10.2 g of 1,1-bistrifluoromethyl-2-fluoro-2-propene-1-ol: CH₂═CFC(CF₃)₂OH was obtained.

Next, polymerization reaction and separation of a polymer were carried out in the same manner as in Preparation Example 11 except that 10.2 g of 1,1-bistrifluoromethyl-2-fluoro-2-propene-1-ol was used instead of perfluoro-(9,9-dihydro-2,5-bistrifluoromethyl-3,6-dioxa-8-nonenoic acid), and 6.5 g of a colorless transparent polymer was obtained.

According to ¹H-NMR, ¹⁹F-NMR and IR analyses, the obtained polymer was found to be a fluorine-containing polymer containing only a structural unit of the above-mentioned fluorine-containing allyl ether having OH group.

According to GPC analysis, a number average molecular weight of the polymer was 24,000.

### Experimental Example 11

### Preparation of Coating Composition

The fluorine-containing polymers having hydrophilic functional group Y¹ obtained in Preparation Examples 19 to 23 were dissolved in methyl amyl ketone (MAK) at a concentration of 5% by weight, followed by filtration through a 0.2 μm filter, and homogeneous coating compositions were obtained.

### Experimental Example 12

### Measurement of Transparency at 193 nm

Transparency at 193 nm of each coating composition obtained in Experimental Example 11 was measured in the same manner as in Experimental Example 4. The results are shown in Table 8.

### Experimental Example 13

### Measurement of Solubility in a Developing Solution

A dissolution rate (nm/sec) in a developing solution was measured by the quartz crystal oscillation method (QCM method) in the same manner as in Experimental Example 5 except that the coating compositions obtained in Experimental Example 11 were used. The results are shown in Table 8.

### Experimental Example 14

### Measurement of Dissolution Rate in Pure Water

A dissolution rate (nm/min) in pure water was measured by the quartz crystal oscillation method (QCM method) in the same manner as in Experimental Example 6 except that the coating compositions obtained in Experimental Example 11 were used. The results are shown in Table 8.

TABLE 8

| | Transparency | Solubility in a | Solubility in pure |
|---|---|---|---|
| | at 193 nm | developing solution | water |
| | (μm⁻¹) | (nm/sec) | (nm/min) |
| Prep. | 0.2 | 1400 | 1.0 or less |
| Ex. 19 | | | |
| Prep. | 0.2 | 1300 | 1.0 or less |
| Ex. 20 | | | |
| Prep. | 0.2 | 1300 | 1.0 or less |
| Ex. 21 | | | |
| Prep. | 0.2 | 700 | 1.0 or less |
| Ex. 22 | | | |
| Prep. | 0.2 | 800 | 1.0 or less |
| Ex. 23 | | | |

### Example 4

### Formation of Laminated Resist

Laminated resists were formed in the same manner as in Example 1 except that each coating composition prepared in Experimental Example 11 was used for the protective layer (L2), and water contact angles thereof were measured 0 to 10 seconds after and 60 to 70 seconds after. The results are shown in Table 9.

TABLE 9

Water contact angle (degrees)

| | 0 to 30 seconds after | 60 to 90 seconds after |
|---|---|---|
| Prep. Ex. 19 | 88 | 78 |
| Prep. Ex. 20 | 80 | 66 |
| Prep. Ex. 21 | 85 | 72 |
| Prep. Ex. 22 | 85 | 84 |
| Prep. Ex. 23 | 82 | 81 |

### INDUSTRIAL APPLICABILITY

According to the laminated resists of the first and second inventions, a fine pattern of an intended form can be formed without any pattern defect with good reproducibility in the exposing step of immersion lithography wherein the exposing is carried out using ultraviolet light of a wavelength of not less than 193 nm and pure water is used as a liquid medium.

1-10. (canceled)

11. A method for forming a resist pattern by immersion lithography, which comprises:
a step of forming a laminated resist in which a photoresist layer (L3) is formed on a substrate as an outermost surface of the laminated resist and is characterized by containing (A2) a fluorine-containing polymer having protective group Y² which can be converted to an alkali soluble group by dissociation with an acid and (B2) a photoacid generator;
a step of selectively exposing the laminated resist through a mask having a desired pattern and a reduction projection glass by irradiating with ultraviolet light of a wavelength of not less than 193 nm under the condition where pure water is filled between the reduction projection glass and the laminated resist,
a step of post-exposure baking the exposed laminated resist to dissociate the protective group Y² with an acid generated from the photoacid generator (B), and a step of developing the baked laminated resist to form the desired resist pattern.

12. The method of claim 11, wherein a contact angle of water of the photoresist layer (L3) is not less than 70°.

13. The method of claim 11, wherein a contact angle of water of the photoresist layer (L3) is not less than 80°.
